(19) United States
(12) Patent Application Publication
(10) Pub. No.: US 2013/0270517 A1
(43) Pub. Date: Oct. 17, 2013

(54) SUPER LATTICE STRUCTURE, SEMICONDUCTOR DEVICE AND SEMICONDUCTOR LIGHT EMITTING DEVICE HAVING SUPER LATTICE STRUCTURE, AND METHOD OF MAKING SUPER LATTICE STRUCTURE

(71) Applicants: SHARP KABUSHIKI KAISHA, Osaka-shi (JP); THE UNIVERSITY OF TOKYO, Tokyo (JP)

(72) Inventors: Tomohiro NOZAWA, Osaka-Shi (JP); Yasuhiko ARAKAWA, Tokyo (JP); Jun TATEBAYASHI, Tokyo (JP)

(73) Assignees: The University of Tokyo, Tokyo (JP); SHARP KABUSHIKI KAISHA, Osaka-shi (JP)

(21) Appl. No.: 13/779,257

(22) Filed: Feb. 27, 2013

(30) Foreign Application Priority Data
Apr. 16, 2012 (JP) 2012-093240
Aug. 28, 2012 (JP) 2012-187856

(51) Int. Cl. H01L 33/04; H01L 29/15

(52) U.S. Cl. CPC H01L 33/04; H01L 29/15
USPC 257/13; 257/15; 438/478

(57) ABSTRACT

A superlattice structure includes a plurality of quantum-dot nanowires extending in a substantially vertical direction from a plane region. The quantum-dot nanowires have a structure of barrier layers and quantum-dot layers alternately stacked on the plane region, and the quantum-dot nanowires are substantially the same in diameter in a stacking direction and substantially uniformly arranged at an area density of 4 nanowires/μm² or more.

### CROSS-REFERENCE TO RELATED APPLICATION

This application relates to Japanese Patent Applications No. 2012-093240 filed on Apr. 16, 2012 and No. 2012-187856 filed on Aug. 28, 2012, whose priorities are claimed and the disclosures of which are incorporated by reference in their entirety.

### BACKGROUND OF THE INVENTION

1. Field of the Invention

The present invention relates to a superlattice structure, a semiconductor device and a semiconductor light emitting device including the superlattice structure, and a method for manufacturing the superlattice structure.

2. Description of the Related Art

In recent years, photovoltaic elements have been attracting attention as clean energy sources which emit no CO₂, and becoming popular. While the most popular photovoltaic elements now are single-junction solar cells using silicon, the silicon solar cells fail to absorb light in a longer wavelength range in the solar light spectra, and most of solar light energy has been not utilized. Therefore, in order to effectively utilize this solar light energy which has not been utilized, quantum-dot solar cells using quantum dots have been attracting attention.

The quantum dot is a nanostructured particle on the order of several nm to 100 nm, and a superlattice structure including a plurality of quantum dots forms a new band gap (quantum energy level), thereby making it possible to also absorb solar light in a longer wavelength range which has not ever been utilized. In addition, the quantum dot also has features such as that the band gap can be freely controlled by controlling the size of the quantum dot. In the case of applying such a superlattice structure including a plurality of quantum dots to a solar cell, it is extremely important to achieve a superlattice structure that varies little in quantum dot size throughout the superlattice structure, and has high uniformity.

Conventionally, a method referred to as SK (Stranski-Krastanov) growth of forming quantum dots from film growth with the use of strain is known as a method for forming the quantum dot (for example, see Japanese Patent Application Laid-Open No. 2011-86774).

In addition, a top-down approach of forming a nanowire by a method such as partial etching after alternately stacking medium layers and semiconductor layers of several nanometers in thickness is known as a method for forming a quantum-dot nanowire of quantum dots stacked in a nanowire of nanosize in diameter (for example, see Japanese Patent Application Laid-Open No. 2011-530829 and Hua Wang, Minghua Sun, Kang Ding, Martin T. Hill, and Cun-Zheng Ning, Nano Lett. 2011, 11, 1646-1650).

Furthermore, known is a bottom-up approach of forming a nanowire by crystal growth with nanostructures stacked up on a substrate surface by, for example, a VLS (Vapor-Liquid-Solid) method using a noble metal catalyst such as Au (for example, see Japanese Patent Application Laid-Open No. 2009-269170).

In addition, light emitting devices using the quantum dots have been actively researched and developed, and as applications of these devices, light emitting devices for communication wavelength ranges and biological tomographic devices using optical coherence tomography (OCT) have been receiving attention. The light emitting devices for communication wavelength ranges have a feature of achieving higher output power with more highly uniform and higher-density quantum dots. On the other hand, the light emitting devices for OCT have a feature of achieving higher resolutions as the emission wavelength range has a broadband and Gaussian spectrum. The range from 0.7 μm to 1.3 μm is suitable as the emission wavelength band for OCT. This is because the absorption of melanin and hemoglobin in vivo is increased in a visible region of 0.7 μm or less, whereas the absorption of moisture is increased in the visible region of 1.3 μm or more. As an example of these biological tomographic devices, an optical tomographic image-capturing device has been proposed which uses an optical semiconductor element including a light emitting layer formed from three different types of quantum-dot layers in terms of center wavelength (for example, see Japanese Patent Application Laid-Open No. 2008-270585).

However, the method of forming the quantum dots through the use of SK growth uses energy of lattice strain due to differences in lattice constant from substrate crystals (lattice mismatch), and the quantum-dot layer formed by SK growth is thus likely to be affected by the influence of strain, and becomes increasingly likely to be affected by the influence of strain with progression of stacking. Therefore, the quantum-dot layer will become non-uniform as the layer is highly stacked.

In addition, the quantum-dot nanowire formed by the top-down approach such as an etching method is likely to be defective because strain is caused at the stage of thin film formation before the etching, and the influence of the strain may remain. In particular, in the case of forming a highly-stacked quantum-dot nanowire, vertical etching is difficult because of anisotropy, and thus, the quantum-dot layer may vary in size, and produce remarkable non-uniformity.

Furthermore, while the quantum-dot nanowire formed by the bottom-up approach such as the VLS method is less likely to be affected by the influence of strain as compared with the quantum-dot nanowire formed by SK growth, there is a tendency to fail to keep the uniformity and undergo a decrease in diameter as the nanowire is highly stacked, and the quantum-dot layer may vary in size between the bottom and top thereof. In addition, in the case of preparing a large number of quantum-dot nanowires, the respective quantum-dot nanowires are not necessarily uniform in properties such as diameter, verticality to the substrate, and size for each quantum-dot layer, and in particular, in the case of forming highly-stacked quantum-dot nanowires, this non-uniformity may be remarkably produced.

In addition, when, after the formation of quantum-well thin films, the strain thereof is used to stack quantum dots in a self-organizing manner, many dislocations and defects are caused, and there is thus possibility that the luminous efficiency will be decreased significantly. In addition, it is generally not easy to control the sizes of the quantum dots prepared in a self-organizing manner, and multiply-stacked quantum dots of different sizes also have the possibility of making the preparation of quantum dots further difficult, also make it further difficult to control the sizes of quantum dots, and thus have the problem of failing to easily obtain desired emission spectra.

In view of these circumstances, superlattice structures have been desired which keep the quantum dot layers in quantum-dot nanowires uniform in size even in highly-stacked cases, and also vary little in quantum-dot layer size between quantum-dot nanowires.

### SUMMARY OF THE INVENTION

An object of the present invention is to provide a superlattice structure which has smaller numbers of dislocations and defects even with multiply-stacked quantum dots of different sizes on the same substrate, and a semiconductor light emitting device including the superlattice structure, which has a high luminous efficiency with low power consumption.

The present invention provides a superlattice structure comprising a plurality of quantum-dot nanowires extending in a substantially vertical direction from a plane region, wherein the quantum-dot nanowires have a structure of barrier layers and quantum-dot layers alternately stacked on the plane region, and the quantum-dot nanowires are substantially the same in diameter in a stacking direction, and substantially uniformly arranged at an area density of 4 nanowires/pmt or more.

Furthermore, the present invention provides a method for manufacturing a superlattice structure, which comprises the steps of: forming a mask layer on a plane region; providing a plurality of openings with an area density of 4 openings/μm² or more in the mask layer; and forming a plurality of quantum-dot nanowires by alternately stacking barrier layers and quantum-dot layers in a substantially vertical direction through the plurality of openings.

According to the present invention, the quantum-dot layers, even highly stacked, in the quantum-dot nanowires are kept uniform in size because the quantum-dot nanowires are substantially the same in diameter in the stacking direction, and a superlattice structure can be achieved which also varies little in quantum-dot layer size between the quantum-dot nanowires, because the quantum-dot nanowires are substantially uniformly arranged at an area density of 4 nanowires/μm² or more.

Furthermore, the method according to the present invention comprises the steps of: forming a mask layer on a plane region; providing a plurality of openings with an area density of 4 openings/μm² or more in the mask layer; and forming a plurality of quantum-dot nanowires by alternately stacking barrier layers and quantum-dot layers in a substantially vertical direction through the plurality of openings, and a mode is thus dominant in which raw materials supplied for the formation of the quantum-dot nanowires are directly stacked for the quantum-dot nanowires. Therefore, a method can be achieved for producing a superlattice structure which has small strain even in highly-stacked cases, keeps the quantum-dot layers in the quantum-dot nanowires uniform in size, and also varies little in quantum-dot layer size between the quantum-dot nanowires.

### BRIEF DESCRIPTION OF THE DRAWINGS

FIGS. 1A to 1H are diagrams illustrating a process for manufacturing a solar cell including a superlattice structure according to a first embodiment of the present invention;

FIG. 2 is a diagram illustrating a structure of a solar cell according to the first embodiment of the present invention;

FIGS. 3A to 3D are diagrams illustrating the relationship between the quantum-dot to quantum-dot distance in a quantum-dot nanowire according to the first embodiment of the present invention and a band structure of the dot;

FIGS. 4A to 4D are SEM and TEM observation images of the superlattice structure according to the first embodiment of the present invention;

FIG. 5 is a SEM observation image of the superlattice structure according to the first embodiment of the present invention;

FIG. 6 is a PL measurement result of the superlattice structure according to the first embodiment of the present invention;

FIGS. 7A and 7B are plan views illustrating configurations according to a modification example of the superlattice structure according to the first embodiment of the present invention;

FIG. 8 is a cross-sectional view illustrating a structure according to a modification example of the solar cell according to the first embodiment of the present invention;

FIGS. 9A to 9H are diagrams illustrating a process for manufacturing a solar cell including a superlattice structure according to a second embodiment of the present invention;

FIG. 10 is a diagram illustrating the structure of a solar cell according to the second embodiment of the present invention;

FIGS. 11A to 11C are plan views illustrating configurations according to a modification example of the superlattice structure according to the second embodiment of the present invention;

FIGS. 12A to 12C are plan views illustrating configurations according to a second modification example of the superlattice structure according to the second embodiment of the present invention;

FIGS. 13A to 13H are diagrams illustrating a process for manufacturing a solar cell including a superlattice structure according to a third embodiment of the present invention;

FIGS. 14A to 14H are diagrams illustrating a process for manufacturing a solar cell including a superlattice structure according to a fourth embodiment of the present invention;

FIGS. 15A to 15H are diagrams illustrating a process for manufacturing a semiconductor light emitting device including a superlattice structure according to a fifth embodiment of the present invention;

FIG. 16 is a diagram illustrating a structure of the semiconductor light emitting device according to the fifth embodiment of the present invention;

FIG. 17 is a diagram schematically illustrating band structures of quantum-dot nanowires shown in FIG. 16;

FIG. 18 is a diagram illustrating a structure according to a modification example of the semiconductor light emitting device shown in FIG. 16;

FIG. 19 is a diagram illustrating a structure according to a modification example of the semiconductor light emitting device shown in FIG. 16;

FIG. 20 is a graph showing the relationship between the length between quantum-dot layers in the quantum-dot nanowire in FIGS. 3A to 3D, and emission peak energy of the layer;

FIGS. 21A and 21B are diagrams illustrating the relationship between a barrier layer length in a quantum-dot nanowire and a band structure of the layer;

FIGS. 22A to 22H are diagrams illustrating a process for manufacturing a semiconductor light emitting device including a superlattice structure according to a sixth embodiment of the present invention;

FIGS. 23A to 23D are diagrams illustrating the relationship between a length of a quantum-dot layer in the quantum-dot nanowire in FIGS. 22E to 22H and a diagram schematically illustrating the band structure of the layer;

FIG. 24 is a graph showing the relationship between the length of the quantum-dot layer in the quantum-dot nanowire in FIGS. 23A to 23D, and emission peak energy of the layer;

FIGS. 25A and 25B are diagrams illustrating the relationship between the length of a quantum-dot layer in a quantum-dot nanowire and a diagram schematically illustrating the band structure of the layer;

FIGS. 26A and 26B are graphs showing emission spectra of the quantum-dot nanowire in FIGS. 25A and 25B;

FIGS. 27A to 27H are diagrams illustrating a process for manufacturing a semiconductor light emitting device including a superlattice structure according to a seventh embodiment of the present invention; and

FIGS. 28A and 28B are diagrams illustrating the relationship between a quantum-dot layer composition in a quantum-dot nanowire and a diagram schematically illustrating a band structure of the layer.

### DETAILED DESCRIPTION OF THE PREFERRED EMBODIMENTS

The superlattice structure according to the present invention includes a plurality of quantum-dot nanowires extending in a substantially vertical direction from a plane region. The quantum-dot nanowires have a structure of barrier layers and quantum-dot layers alternately stacked on the plane region, and the quantum-dot nanowires are substantially the same in diameter in a stacking direction and substantially uniformly arranged at an area density of 4 nanowires/μm² or more.

Furthermore, the method for manufacturing a superlattice structure according to the present invention comprises the steps of: forming a mask layer on a plane region; providing a plurality of openings with an area density of 4 openings/μm² or more in the mask layer; and forming a plurality of quantum-dot nanowires by alternately stacking barrier layers and quantum-dot layers in a substantially vertical direction through the plurality of openings.

The phrase “substantially vertical direction” refers to the orientation of the quantum-dot nanowire with an angle of 75 degrees to 90 degrees, and more preferably 85 degrees to 90 degrees between the base material (substrate) surface or plane region and the quantum-dot nanowire.

The phrase “substantially the same in diameter in the stacking direction” means that the variation in diameter in the stacking direction (the magnitude of the deviation from an average value) is 15% or less in a quantum-dot nanowire. The difference in diameter between any two points in a quantum-dot nanowire is preferably 15% or less of the average diameter, further preferably, the difference in diameter between two specific points (preferably the center and an end of the quantum-dot nanowire, further preferably the center and top of the quantum-dot nanowire, and further preferably positions of the quantum-dot nanowire on the order of several nm away from each other) is 15% or less of the average diameter, and further preferably, the difference in diameter is 15% or less of the average diameter over the entire quantum-dot nanowire.

While the uniformity of the quantum-dot nanowires has been described above, the uniformity of the quantum dots is also preferably established.

The phrase “substantially uniformly arranged” means that the variation in distance between the centers of any quantum-dot nanowires (the magnitude of the deviation from an average value) is 15% or less.

In addition, the phrase means that the variation in diameter (the magnitude of the deviation from an average value) is 15% or less among the plurality of quantum-dot nanowires as viewed from above. In a plane region of 1 μm square, the difference in diameter between any two quantum-dot nanowires is preferably 15% or less of the average diameter, and further preferably, the variation in diameter is 15% or less among the plurality of quantum-dot nanowires.

Moreover, the magnitude of the deviation is preferably 10% or less.

The term “structure” refers to a quantum-dot nanowire structure configured by stacking with any different types of quantum-dot layer lengths, composition ratios, and materials, barrier layer lengths, composition ratios, and materials, and intervals (lengths) between quantum-dot nanowires, etc.

The term “mask layer” refers to a layer that forms no energetically stable materials with raw materials for the quantum-dot nanowires, and that includes a material in which the raw materials for the quantum-dot nanowires are sufficiently large in diffusion length. With the use of this mask layer, even when raw materials supplied for the formation of the quantum-dot nanowires temporarily put on the mask layer, the raw materials on the mask layer, because of being energetically unstable, run up onto energetically more stable quantum-dot nanowires. Therefore, the raw materials are not stacked on the mask layer, but stacked on quantum-dot nanowires, and highly uniform quantum-dot nanowires can be thus formed. It is to be noted that materials for the mask layer include SiO₂ in the case of using InAs or GaAs as a material for the quantum-dot nanowire.

Furthermore, in the superlattice structure according to the present invention, the quantum-dot nanowires may have at least two types of diameters.

Thus, the superlattice structure can efficiently absorb a wide wavelength range of the solar light spectrum, because the structure includes the quantum-dot nanowires which have at least two types of diameters.

Furthermore, in the superlattice structure according to the present invention, there may be further, on a base material surface including at least two types of plane regions, different structures arranged for each type of the plane regions.

Thus, the formation of, on a substrate surface including at least two types of plane regions, differently structured quantum-dot nanowires for each type of the plane regions, with any combination of quantum-dot layer lengths, composition ratios, and materials, barrier layer lengths, composition ratios, materials, and intervals between quantum-dot nanowires, etc, can freely control the physical characteristics (light absorption characteristics, light emission characteristics, etc.) for each plane region, and achieve a superlattice structure having desired physical characteristics over the entire plane regions.

Furthermore, in the method for manufacturing a superlattice structure according to the present invention, the mask layer may be formed on a base material surface including at least two types of plane regions.

Thus, through the formation of a mask layer on the substrate according to the present invention and the selective growth of quantum-dot nanowires from openings provided substantially uniformly at an area density of 4 openings/μm² or more, the formation of differently structured quantum-dot nanowires for each type of the plane regions, with a combination of any different types of quantum-dot layer lengths, composition ratios, and materials, barrier layer lengths, composition ratios, materials, and intervals between quantum-dot nanowires, etc, without the generation of dislocations, defects, and strains, can freely control the physical characteristics (light absorption characteristics, light emission characteristics, etc.) for each plane region, and achieve a superlattice structure which has desired physical characteristics over the entire plane regions.

Furthermore, in the superlattice structure according to the present invention, the quantum-dot nanowires may have the quantum-dot layers of at least two types of lengths in the stacking direction.

Thus, because the quantum-dot nanowires have the quantum-dot layers of at least two types of lengths in the stacking direction, various bandgaps can be formed, and a wide wavelength range of the solar light spectrum can be thus efficiently absorbed. In addition, it is possible to form high-quality quantum-dot layers without any dislocations.

The use of the approach according to the present invention can form the quantum-dot layers included in a quantum-dot nanowire so as to have high quality, and thus change the quantum-dot layers included in a quantum-dot nanowire in size intentionally in a controllable manner, significantly unlike the top-down approach using the SK growth or etching technique.

In addition, a diversity of physical characteristics can be achieved from the quantum-dot layers of multiple types of lengths constituting the quantum-dot nanowire. For example, when the superlattice structure is used for a light emitting device, a light emission that has any spectrum distribution with a diversity of colors mixed can be achieved by summing light emissions from the plurality of types of quantum-dot layers constituting the quantum-dot nanowire.

Furthermore, in the superlattice structure according to the present invention, the quantum-dot nanowires may have the quantum-dot layers of at least two types of compositions.

Thus, it is possible to form high-quality quantum-dot layers without any dislocations by changing the compositions of the quantum-dot layers, because the quantum-dot nanowires have the quantum-dot layers of at least two types of compositions. In addition, the quantum-dot layers in one quantum-dot nanowire can be intentionally changed in size in a controllable manner.

The “composition” of the quantum-dot layer herein includes the material, mixed crystal ratio, etc.

In addition, the quantum-dot layers constituting the quantum-dot nanowire can be freely changed in composition and material, and a diversity of physical characteristics can be thus achieved. For example, when the superlattice structure is used for a light emitting device, light of various emission wavelengths can be obtained, and a broadband Gaussian-type emission spectrum can be thus obtained to achieve a low-power-consumption semiconductor light emitting device.

Furthermore, in the superlattice structure according to the present invention, the quantum-dot nanowires may have the barrier layers of at least two types of lengths in the stacking direction.

Thus, when the interval between the quantum-dot nanowires is changed by adjusting the lengths of the barrier layers constituting the quantum-dot nanowires in the stacking direction, the proportions of elements incorporated into the quantum-dot layers can be varied among the quantum-dot nanowires, and a diversity of physical characteristics can be achieved. For example, when the superlattice structure is used for a light emitting device, light of various emission wavelengths can be obtained.

Furthermore, in the superlattice structure according to the present invention, an interval between the quantum-dot nanowires adjacent to each other may be 30 nm to 500 nm.

Thus, a superlattice structure can be achieved which varies little in quantum-dot layer size between quantum-dot nanowires and has quantum-dot nanowires provided at a high density, because the interval between the quantum-dot nanowires adjacent to each other is 30 nm to 500 nm. More preferably, the interval between the quantum-dot nanowires adjacent to each other may be 30 nm to 200 nm.

Furthermore, in the superlattice structure according to the present invention, the quantum-dot nanowires may have a diameter of 5 nm to 100 nm.

Thus, a superlattice structure can be achieved which varies little in quantum-dot layer size between quantum-dot nanowires and has quantum-dot nanowires provided at a higher density, because the quantum-dot nanowires have a diameter of 5 nm to 100 nm. In addition, solar energy can be absorbed efficiently which correspond to the sizes of the quantum-dot layers included in the quantum-dot nanowires.

Furthermore, in the superlattice structure according to the present invention, the quantum-dot nanowires may have 30 to 600 layers of the quantum-dot layers.

Thus, a superlattice structure can be achieved which varies little in size among the quantum-dot layers, even highly stacked, in the quantum-dot nanowires and has quantum-dot nanowires provided at a high density, because the quantum-dot nanowires have 30 to 600 layers of the quantum-dot layers.

Furthermore, in the superlattice structure according to the present invention, the quantum-dot nanowires may have different diameters for each type of the plane regions.

Thus, the quantum-dot nanowire diameter varied for each type of the plane regions can vary the proportions of elements incorporated in the quantum-dot layers and the lengths of the quantum dots in the staking direction among the quantum-dot nanowires, and achieve a diversity of physical characteristics in the single superlattice structure. For example, when the superlattice structure is used for a light emitting device, light of various emission wavelengths can be obtained.

Furthermore, in the superlattice structure according to the present invention, the quantum-dot nanowires may have different compositions for each type of the plane regions.

Thus, a diversity of physical characteristics can be achieved in the single superlattice structure by varying the proportions of elements incorporated in the quantum-dot layers for each type of the plane regions among the quantum-dot nanowires. For example, when the superlattice structure is used for a light emitting device, light of various emission wavelengths can be obtained.

Furthermore, in the superlattice structure according to the present invention, the quantum-dot nanowires may have different area densities for each type of the plane regions.

Thus, the quantum-dot nanowire area density varied for each type of the plane regions can vary the proportions of elements incorporated in the quantum-dot layers and the lengths of the quantum dots in the staking direction among the quantum-dot nanowires, and achieve a diversity of physical characteristics in the single superlattice structure. For example, when the superlattice structure is used for a light emitting device, light of various emission wavelengths can be obtained.

Furthermore, in the superlattice structure according to the present invention, the quantum dot density may be 1.0×10¹¹/cm² to 1.0×10¹³/cm².

Thus, a superlattice structure can be achieved which varies little in quantum-dot layer size in quantum-dot nanowires and has quantum-dot nanowires provided at a high density, because the quantum dot density is 1.0×10¹¹/cm² to 1.0×10¹³/cm².

The “density” herein refers to an area density also in consideration of height direction, which is the quantum dot area density per 1 cm² layer multiplied by the number of quantum-dot layers.

Furthermore, in the superlattice structure according to the present invention, the quantum-dot nanowires may be arranged periodically with a constant repeating period, as viewed from a direction perpendicular to the plane region.

Thus, because the quantum-dot nanowires are arranged periodically with a constant repeating period, as viewed from a direction perpendicular to the plane region, in the superlattice structure, the plurality of quantum-dot nanowires influence one another in a synergistic manner, and when the superlattice structure is applied to a solar cell or the like, optical confinement between the quantum-dot nanowires will be induced efficiently, and solar light can be absorbed efficiently. In addition, solar light can be effectively absorbed, and thus, the amounts of materials used can be reduced dramatically as compared with thin-film quantum-dot structures formed by SK growth or the like, thereby leading to a reduction in cost.

Furthermore, as for the quantum-dot nanowire structure in the superlattice structure according to the present invention, a ratio of the structure to the plane region may be 5% or more when the plane region is viewed from the stacking direction.

Thus, because as for the quantum-dot nanowire structure, the ratio of the structure to the plane region is 5% or more when the plane region is viewed from the stacking direction, a superlattice structure is achieved which varies little in quantum-dot layer size in quantum-dot nanowires and has quantum-dot nanowires provided at a high density. In addition, solar light can be absorbed adequately.

Furthermore, in the superlattice structure according to the present invention, the ratio may be 5% to 50%.

Thus, a superlattice structure can be achieved which varies little in quantum-dot layer size in quantum-dot nanowires and has quantum-dot nanowires provided at a high density, because the ratio is 5% to 50%. In addition, solar light can be absorbed adequately.

Furthermore, in the superlattice structure according to the present invention, the quantum-dot layers or the barrier layers may be n-type doped.

Thus, carriers are allowed to flow efficiently, because the quantum-dot layers or the barrier layers may be n-type doped.

Furthermore, instead of n-type doping the quantum-dot layers or the barrier layers, a shell layer may be formed so as to cover both sides of the quantum-dot layers and barrier layers stacked in the quantum-dot nanowires, and may be n-type doped. Thus, electrons generated in the quantum-dot layers flow into the shell layer, so that carriers can be allowed to flow efficiently.

Furthermore, separately from the n-type doped shell layer, or instead of the n-type doped shell layer, a p-type doped shell layer may be provided. Thus, holes generated in the quantum-dot layers flow into the shell layer, so that carriers is allowed to flow efficiently.

Furthermore, in the superlattice structure according to the present invention, the quantum-dot layers and the barrier layers may include AlInGaAs or AlInGaN.

Thus, because the quantum-dot layers and the barrier layers include AlInGaAs or AlInGaN, uniform quantum-dot nanowires can be formed which have small strain even in highly-stacked cases, and a highly uniform superlattice structure can be achieved which has desired physical characteristics for each type of the plane regions.

Furthermore, the superlattice structure according to the present invention has at least one unit structure, which may have a structure of at least six quantum-dot nanowires closely arranged at regular intervals around one quantum-dot nanowire.

Thus, because the superlattice structure has at least one unit structure, which may have a structure of at least six quantum-dot nanowires closely arranged at regular intervals around one quantum-dot nanowire, high-density and highly uniform stacking is made possible to achieve a superlattice structure which varies little in quantum-dot layer size between the quantum-dot nanowires.

Furthermore, in the superlattice structure according to the present invention, the area density may be 20 to 100 nanowires/μm² or more.

Thus, a superlattice structure can be achieved which varies little in quantum-dot layer size in quantum-dot nanowires and has quantum-dot nanowires provided at a high density, because the area density is 20 to 100 nanowires/μm² or more. In addition, solar light can be absorbed adequately.

In addition, in the superlattice structure according to the present invention, the quantum-dot nanowires may contain no metal impurity elements in excess of background concentrations.

Thus, because the quantum-dot nanowires contain no metal impurity elements in excess of background concentrations, metal impurities will not be mixed into the quantum-dot nanowires, and highly uniform quantum dots can be achieved.

The “background concentrations” refer to the concentrations of minute amounts of metal impurity elements contained in the substrate and in atmospheric components.

Furthermore, the superlattice structure according to the present invention may have a structure filled with a wavelength conversion material between the quantum-dot nanowires.

Thus, the wavelengths of solar light can be converted depending on the quantum dot size to increase the efficiency, because the superlattice structure has a structure filled with a wavelength conversion material between the quantum-dot nanowires.

In addition, the wavelength conversion material isotropically radiates light, and thus has a possibility of producing useless light that is not radiated toward a solar cell, for example, when the wavelength conversion material is placed on the top or bottom of the solar cell. However, when the structure is filled with the wavelength conversion material between the quantum-dot nanowires, most of light can be prevented from being radiated to the outside of a solar cell because the light is radiated from the inside of the solar cell.

The “wavelength conversion material” refers to a material that converts the wavelength of incident light, examples of which include materials that can shift the wavelengths of solar light, such as ZnO, ZnS, ZnSe, ZnTe, CdS, CdSe, CdTe, PbS, PbSe, PbTe, CuInGaS, CuS, InGaZnO, InAs, GaAs, AlAs, InSb, GaSb, AlSb, InP, GaP, AlP, InN, GaN, MN, Si, and Ge and inorganic materials for mixed crystal materials thereof, complex materials, glass containing rare-earth ions (Er³⁺, Pr³⁺, Tm³⁺, etc.) or transition elements, and Er-doped garnet crystals (YAG). For example, the wavelength conversion material can be used for improvement in energy conversion efficiency through the conversion of light of a wavelength that is not used, or light of a wavelength that is less likely to be used because a small amount of the light is absorbed, to a wavelength suitable for absorption by the quantum-dot layers, and for suppression of solar cell degradation caused by ultraviolet light through the conversion of light in an ultraviolet region to light in a visible region. In addition, the wavelength conversion material filling in nanoscale for quantization is preferable for reasons such as that the wavelength of light for wavelength conversion can be freely controlled, and the wavelength conversion material is easily used for filling between the quantum-dot nanowires.

Furthermore, a semiconductor device including a p-type semiconductor layer, an n-type semiconductor layer, and a superlattice semiconductor layer sandwiched between the p-type semiconductor layer and the n-type semiconductor layer may be provided in which the superlattice semiconductor layer includes the superlattice structure.

Thus, because the superlattice semiconductor layer includes the superlattice structure in the semiconductor structure including the p-type semiconductor layer, the n-type semiconductor layer, and the superlattice semiconductor layer sandwiched between the p-type semiconductor layer and the n-type semiconductor layer, a semiconductor structure can be achieved which includes a superlattice structure including uniform quantum-dot nanowires which have small strain even in highly-stacked cases.

Furthermore, the superlattice semiconductor layer may emit light having at least two types of emission wavelengths.

Thus, a plurality of LEDs for different emission colors (for example, RGB) can be achieved on the same substrate by integrating a plurality of types of quantum dots on the same substrate. In addition, a semiconductor light emitting device with a high luminous efficiency and with low power consumption can be achieved, because the quantum-dot layers have fewer dislocations or defects.

Furthermore, in the semiconductor light emitting device according to the present invention, the superlattice structure may emit light having an emission wavelength for a Gaussian-type emission spectrum over the entire quantum-dot nanowires.

Light emissions with a broadband and Gaussian spectrum can be obtained by summing light emissions from a plurality of types of quantum-dots.

Furthermore, the semiconductor light emitting device according to the present invention may be used as a light emitting device for communication.

Thus, with the use of an optical fiber for an LED including the superlattice structure according to the present invention, the semiconductor light emitting device can be used as a semiconductor light emitting device for communication without using any light combiner.

Furthermore, the superlattice structure according to the present invention can be also used as a detector.

The superlattice structure according to the present invention has the advantage of being large in light emitting and light-receiving area with respect to the area occupied by the substrate, and light emitting devices and light-receiving devices can be thus reduced in size.

### First Embodiment

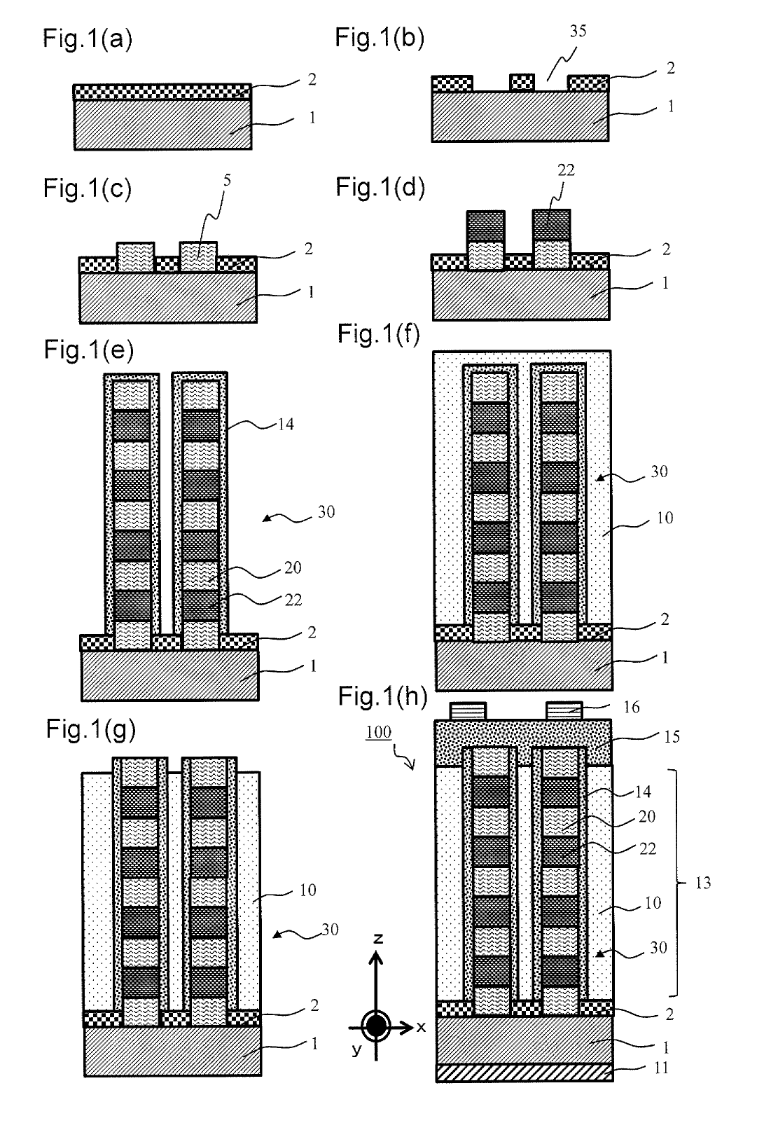

Next, a solar cell 100 according to a first embodiment will be described with reference to FIGS. 1A through 6.

It is to be noted that the following examples are by way of example, and respective materials such as substrates, buffer layers, quantum dots, dopants, electrodes for use in the solar cell 100 including the superlattice structure according to the present invention, cleaning agents, substrate treatment temperatures, manufacturing equipment for use in each process, etc. are not limited to the examples given herein. The same applies to other embodiments.

### <Structure of Solar Cell>

FIGS. 1A to 1H are diagrams illustrating a process for manufacturing a solar cell including a superlattice structure according to the first embodiment of the present invention.

The solar cell 100 according to the first embodiment includes an n-type semiconductor layer 1, a p-type semiconductor layer 15, and a superlattice semiconductor layer 13 sandwiched between the n-type semiconductor layer 1 and the p-type semiconductor layer 15.

The plane region according to the present invention corresponds to the n-type semiconductor layer 1, whereas the superlattice structure according to the present invention corresponds to the superlattice semiconductor layer 13.
1. N-Type Semiconductor Layer (Base Layer) and P-Type Semiconductor Layer (Emitter Layer)

The n-type semiconductor layer 1 (base layer) includes a semiconductor containing an n-type impurity, whereas the p-type semiconductor layer 15 (emitter layer) includes a semiconductor containing a p-type impurity.

The n-type semiconductor layer 1 and the p-type semiconductor layer 15 sandwich the superlattice semiconductor layer 13 to constitute the solar cell 100, and can be formed by, for example, an MOCVD method or a sputtering method.

The p-type semiconductor layer 15 can be electrically connected to a p-type electrode 16, whereas the n-type semiconductor layer 1 can be electrically connected to an n-type electrode 11. Thus, photovoltaic power generated between the p-type semiconductor layer 15 and the n-type semiconductor layer 1 can be outputted through the p-type electrode 16 and the n-type electrode 11 to an external circuit. In addition, a contact layer may be provided between the p-type semiconductor layer 15 and the p-type electrode 16, or between the n-type semiconductor layer 1 and the n-type electrode 11.

### 2. Superlattice Semiconductor Layer

The superlattice semiconductor layer 13 is sandwiched between the n-type semiconductor layer (base layer) 1 and the p-type semiconductor layer (emitter layer) 15. In addition, the superlattice semiconductor layer 13 has a superlattice structure of quantum-dot layers 22 and barrier layers 20 alternately stacked repeatedly. The superlattice structure in the solar cell 100 is formed by a quantum-dot nanowire 30.

The quantum-dot nanowire 30 according to the present invention is characterized in that the quantum-dot layers 22 in the superlattice semiconductor layer 13 are arranged in a high-quality and highly uniform fashion in a controllable manner also in terms of arrangement in the stacking direction (z direction).

The quantum-dot layers 22 include a semiconductor material that has a narrower bandgap than the semiconductor material constituting the barrier layers 20, and have a quantum level on the conduction band side due to the quantum effect. Alternatively, the quantum level may be formed on a valence band side.

The barrier layers 20 include a semiconductor material that has a wider bandgap than the semiconductor material constituting the quantum-dot layers 22, and form potential barriers around the quantum-dot layers 22.

In the first embodiment, for example, the quantum-dot layers 22 including InGaAs and the barrier layers 20 including GaAs can be used as the materials of the quantum-dot layers 22 and barrier layers 20 constituting the superlattice semiconductor layer 13. In addition, the quantum-dot layers 22 including InGaAs, the barrier layers 20 including AlGaAs, the quantum-dot layers 22 including InGaN, the barrier layers 20 including GaN, the quantum-dot layers 22 including InGaAsSb, and the barrier layers 20 including AlGaAsSb can be used. Besides, materials of InAs, GaAs, AlAs, InSb, GaSb, AlSb, InP, GaP, AlP, InN, GaN, AlN, Si, and SiGe, and mixed crystal materials thereof may be used. Furthermore, AlₓGa_{y}In_{1-x-y}As, AlₓGa_{y}In_{1-x-y}P, AlₓGa_{y}In_{1-x-y}N, etc., can be also used. Group III-V compound semiconductors, Group II-VI compound semiconductors, Group IV semiconductors, or mixed crystal materials thereof may be used other than listed above.

The quantum-dot layers 22 including mixed crystals and the barrier layers 20 can, through appropriate changes in the element proportions of the mixed crystals, vary the quantum energy levels or the bandgaps of the barrier layers 20, and reduce the valence band energy offset (the difference in valence band energy between the quantum-dot layer 22 and the barrier layer 20) to zero.

In the first embodiment, the plurality of quantum-dot layers 22 (quantum dots in the z direction) in the single quantum-dot nanowire 30 are all the same in size or including the same material, and minibands 42c and 42v are thus likely to be formed preferably in terms of carrier transfer.

In the case of wishing to form quantum energy levels at the same energy value, the quantum-dot layers 22 may be made uniform in size in all of the x direction, y direction, and z direction.

In addition, as shown in FIG. 1E, the quantum-dot nanowire 30 may have a coated structure (a shell layer 14). The shell layer 14 provided for coating stabilizes a surface of the quantum-dot nanowire 30, and effectively reduces surface recombination. In addition, the shell layer 14 also has the advantage that carriers formed in the quantum-dot layers flow through the shell layer 14 to make it easy to extract the carriers. The shell layer 14 may have the same material as the n-type semiconductor layer 1 or the p-type semiconductor layer 15, or have a different material therefrom. In addition, as a layer for surface stabilization, another layer may be further provided on the outside of the shell layer 14.

It is to be noted that the shell layers 14 and 25 are preferably not excessively thick because the high-quality quantum-dot layers 22 can be highly stacked by relaxing strain in the x and y directions, while the moderate shell layers 14 and 25 are preferred for the structure of the solar cell 100.

As shown in FIG. 1F, the gap between the quantum-dot nanowires 30 in the superlattice semiconductor layer 13 is filled with a resin 10 such as, for example, BCB (benzocyclobutene). In addition, for the resin 10, the same material as the barrier layers 20 may be used, or semiconductor materials which are able to absorb solar light may be used unlike the barrier layers 20.

The quantum-dot nanowires 30 preferably contain an n-type dopant (an n-type impurity). Thus, electrons can be present in the quantum-dot layers 22. The n-type dopant may be present in the quantum-dot layers 22, or present in the barrier layers 20. The presence of electrons at a quantum energy level in the quantum-dot layers 22 can increase the optical transition through an intermediate energy level, and improve the incident photon-to-current conversion efficiency of the solar cell 100.

In addition, the quantum-dot nanowires 30 preferably contain an activated n-type dopant at an atomic concentration on the order of 0.5 times as high as the total number of states per unit volume for the quantum energy level.

The total number of states per unit volume for the quantum energy level herein refers to the doubled number of quantum energy levels per unit volume in consideration of spin.

It is to be noted that it is necessary to adopt a strain-relaxed structure in order to form the quantum-dot nanowires 30 of high quality. Therefore, the diameter of the quantum-dot nanowire 30 may be more preferably a critical diameter or smaller. The “critical diameter” herein refers to the diameter of the quantum-dot nanowire 30, with which the quantum-dot layers 22 can, without being strained, grow to the quantum-dot nanowire 30. In general, strain is relaxed as the diameter of the quantum-dot nanowire 30 is smaller, and it is thus possible to grow the quantum-dot nanowires with almost no strain.

On the other hand, in the case of film formation by etching, because of close packing (infinite in length as compared with the nanowire size) in a direction perpendicular to the stacking direction, strain is not able to be relaxed in the direction, and the quantum-dot layers and the host material undergo a decrease in crystalline quality.

The diameter of the quantum-dot nanowire 30 is preferably 5 nm to 100 nm, and more preferably 5 nm to 70 nm. For example, when an In0.3Ga0.7As/GaAs material is used, the critical film thickness is approximately 100 nm because of the difference in lattice constant on the order of 2%, and the quantum-dot nanowire 30 may be configured to have a diameter of 100 nm or smaller. On the other hand, when the diameter is smaller than 5 nm, the control will be hard.

In addition, the quantum-dot nanowires 30 are preferably formed at an interval (the interval of the gap between the two quantum-dot nanowires 30) of 30 nm to 500 nm. Further, the quantum-dot nanowires 30 are preferably formed at an interval of 30 nm to 200 nm. This is because solar light has a wavelength of 500 nm for high radiant energy, and the quantum-dot nanowires 30 formed within the interval can efficiently absorb solar light. In addition, when the interval between the quantum-dot nanowires 30 is substantially smaller than wavelengths of solar light (for example, 200 nm or less), efficient absorption is considered more likely to be achieved due to the periodic structures of the quantum-dot nanowires 30, with particularly reduced influences such as reflection of solar light. On the other hand, the interval of 30 nm or less between the quantum-dot nanowires 30 has a possibility of making it hard to form the quantum-dot nanowires 30.

In addition, it is preferable to form the quantum-dot nanowires 30 at the interval mentioned above, and form quantum-dot nanowires 30 of different types of diameters, on at least one basis for each diameter, in a region in the x-y plane on the order of a solar light wavelength (for example, on the order of 500 nm) or less. Further preferably, it is preferable to form quantum-dot nanowires 30 of different types of diameters, on at least one basis for each diameter, in a region in the x-y plane on the order of a ultraviolet light wavelength, 300 nm or less. Thus, solar light can be absorbed efficiently.

As other structures, contact layers, window layers, BSF (Back Surface Field) layers, antireflection films, etc. may be inserted appropriately, if necessary.

In addition, the p-type electrode 16 and the n-type electrode 11 may be provided respectively on the surface and rear surface. The p-type electrode 16 and the n-type electrode 11 may have a grid-like form.

### 3. Method for Manufacturing Solar Cell

Next, a method for manufacturing the solar cell 100 according to the first embodiment will be described with reference to FIGS. 1A to 1H.

The superlattice semiconductor layer 13 can be prepared by the use of a molecular beam epitaxy (MBE) method, metalorganic chemical vapor deposition (MOCVD) method and the like. The mixed crystal ratio of the quantum-dot layers 22 and the size of the quantum-dot layers 22 can be adjusted by changing composition ratios of raw materials, growth temperatures, pressures, deposition time, etc.

On the method for manufacturing the solar cell 100, the solar cell 100 including a superlattice structure can be manufactured by the use of, for example, a molecular beam epitaxy (MBE) method, a metalorganic chemical vapor deposition (MOCVD) method, or the like which is excellent in film thickness control. The method for manufacturing the solar cell 100 (selective growth) will be described now with reference to FIGS. 1A to 1H.

For example, an n-GaAs(111)B substrate (n-type semiconductor layer 1) is cleaned with an organic cleaning solution, then etched with a sulfuric acid etching solution, and further subjected to water cleaning, and subsequently, an SiO₂ film is stacked as the mask layer 2 as shown in FIG. 1A.

The mask layer 2 is a layer that forms no energetically stable materials with raw materials for the quantum-dot nanowires, and that includes a material in which the raw materials for the quantum-dot nanowires are sufficiently large in diffusion length. Materials for the mask layer 2 include SiO₂ in the case of using InAs or GaAs as a material for the quantum-dot nanowire.

After stacking the mask layer 2, subsequently, as shown in FIG. 1B, openings 35 are formed in the SiO₂ film with the use of, for example, electron lithography. In the first embodiment, the openings 35 have the same diameter as shown in FIG. 1B. In addition, techniques such as nanoimprint technology may be used instead of electron lithography.

Subsequently, the n-type semiconductor layer 1 is placed in an MOCVD system. As shown in FIG. 1C, core layers 5 are formed on the n-type semiconductor layer 1. The core layers 5 preferably use the same material as the n-type semiconductor layer 1, but may use different materials therefrom. The core layers 5 also have a role as buffer layers, and serve as layers for improving the crystalline quality of light absorption layers to be formed thereon, and for example, GaAs layers are formed as the core layers 5.

Subsequently, the quantum-dot layers 22 and the barrier layers 20 are formed on the core layers 5, for which there are a growth mode of stacking a raw material in a gas phase directly on the quantum-dot nanowires 30 and a growth mode of stacking a raw material diffused from the mask onto the quantum-dot nanowires. Even when raw materials supplied for the formation of the quantum-dot nanowires 30 temporarily put on the mask layer 2, the raw materials on the mask layer 2, because of being energetically unstable, evaporate again or run up onto the energetically more stable quantum-dot nanowires 30. Therefore, the raw materials are not stacked on the mask layer 2, but stacked on the quantum-dot nanowires 30, and it thus becomes possible to grow a semiconductor layer of the quantum-dot layers 22 and barrier layers 20 only on the quantum-dot nanowires 30, while the semiconductor layer of the quantum-dot layers 22 and barrier layers 20 is not formed on the mask layer 2.

Subsequently, quantum-dot layers 22 are formed as shown in FIG. 1D. For example, In_{0.3}Ga_{0.7}As is used as a material for the quantum-dot layers 22. It is possible to grow the quantum-dot layers 22 only on the quantum-dot nanowires 30 almost without growing in the x and y directions under specific conditions (hereinafter, referred to as axial growth).

In the axial growth, during the nanowire formation, there are considered to be two modes: the growth mode of stacking a raw material in a gas phase directly on the quantum-dot nanowires; and the growth mode of stacking a raw material diffused from the mask layer 2 onto the quantum-dot nanowires, as mentioned previously. When the quantum-dot nanowire density is low, the mode of growing raw materials directly onto nanowires during nanowire growth is made dominant by providing openings to serve as a basis for nanowire growth at a high density in the mask layer 2, and nanowires with high uniformity even in highly-stacked cases are thus considered to be achieved.

The area density of openings 35 is preferably 4 openings/μm² or more, further preferably 16 openings/μm² or more, further preferably 25 openings/μm² or more, further preferably 36 openings/μm² or more, and further preferably 100 openings/μm² or more.

Furthermore, as for the structure of the quantum-dot nanowires 30, the ratio of the structure to the plane region may be 5% or more, and further preferably 5% to 50% or more, when the plane region is viewed from the stacking direction (above in the z direction).

With this increased density, the mode of stacking raw materials directly onto nanowires during nanowire growth is made dominant, and thus, in addition to the achievement of nanowires with high uniformity even in highly-stacked cases, another feature is that solar light can be absorbed efficiently when the structure is applied to a solar cell device, thereby increasing the energy conversion efficiency of the solar cell.

When quantum-dot nanowires are arranged in a totally random manner, it is difficult to uniformly grow the quantum-dot nanowires because the growth conditions for each quantum-dot nanowire vary according to the effect of the surrounding quantum-dot nanowires. However, the periodic arrangement of quantum-dot nanowires at a high density equalizes the growth conditions for each quantum-dot nanowire, and quantum-dot nanowires with high uniformity can be thus achieved. In addition, because the quantum-dot nanowires are arranged periodically with a constant repeating period, the plurality of quantum-dot nanowires influence one another in a synergistic manner, and when the structure is applied to a solar cell or the like, optical confinement between the quantum-dot nanowires will be induced efficiently, and solar light can be absorbed efficiently. In particular, when the interval between the quantum-dot nanowires is smaller than wavelengths of solar light (for example, 200 nm or less), efficient absorption is considered more likely to be achieved due to the periodic structure, with reduced influences such as reflection of solar light. In addition, solar light can be effectively absorbed, and thus, the amounts of materials used can be reduced dramatically as compared with thin-film quantum-dot structures formed by SK growth or the like, thereby leading to a reduction in cost.

The use of the manufacturing method can determine the growth positions of the quantum-dot nanowires in advance, thus facilitating the growth of the nanowires with a constant period, and making it possible to form a quantum-dot nanowire structure with a constant period.

The structure of the quantum-dot nanowires 30 formed by the axial growth has strain relaxed in the x and y directions, so that strain energy will not be accumulated in the quantum-dot layers 22. Thus, the high-quality and highly uniform quantum-dot layers 22 can be formed in the quantum-dot nanowires 30, without causing any dislocations, and almost without variation in the size of the quantum-dot layer 22. Therefore, the high-quality quantum-dot nanowires 30 can be formed in a direction perpendicular to the n-type semiconductor layer 1 (z direction) as shown in FIG. 1E, by alternately supplying the material required for the formation of the quantum-dot layer 22 and the material required for the formation of the barrier layers 20.

The stacking number of the thus stacked quantum-dot layers 22 which have a substantially uniform size is preferably is 2 or more, further preferably 5 or more, further preferably 10 or more, further preferably 30 or more, further preferably 50 or more, further preferably 100 or more, further preferably 300 or more, and further preferably 600 or more per quantum-dot nanowire.

For example, when the number of the layers is 30, it is possible to achieve the area density of quantum dots on the order of 1.0×10¹¹/cm² to 5.0×10¹¹/cm², and for example, when the number of the layers is 600, it is possible to achieve the area density on the order of 1.0×10¹¹/cm² to 1.0×10¹³/cm².

It is to be noted that when the highly-stacked quantum-dot nanowires 30 were actually prepared by using the method according to the present invention, it was confirmed that at least 600 quantum-dot layers 22 were formed uniformly. The formation of these highly stacked quantum dots can sufficiently absorb solar light, thereby achieving a solar cell with a high energy conversion efficiency.

The quantum-dot nanowires 30 preferably contain an n-type dopant (an n-type impurity). The quantum-dot layers 22 may be doped directly with the n-type dopant (n-type impurity), or the barrier layers 20 may be subjected to δ doping with the n-type dopant (n-type impurity). The “δ doping” refers to doping a limited area with an impurity. As an approach for the doping, a dopant material (for example, silane) may be introduced simultaneously in forming the quantum-dot layers 22 or the barrier layers 20. The quantum-dot layers 22 can be doped with the n-type dopant (n-type impurity) to make electrons present in the quantum-dot layers 22. The presence of electrons in the quantum-dot layers 22 can increase the optical transition through an intermediate energy level, and improve the incident photon-to-current conversion efficiency of the solar cell 100.

In addition, the quantum-dot nanowires 30 preferably contain therein an activated n-type dopant at an atomic concentration on the order of 0.5 times as high as the total number of states per unit volume for the quantum energy level. The total number of states per unit volume for the quantum energy level herein refers to the doubled number of quantum energy levels per unit volume in consideration of spin.

As shown in FIG. 1E, the shell layer 14 may be formed after forming the quantum-dot nanowires 30. It is to be noted that a material containing a p-type dopant such as Zn (for example, Diethylzinc: DEZ) is introduced simultaneously as a raw material in order to form the shell layer 14 as a p-type semiconductor layer.

Further, the shell layer 14 of p-type semiconductor may be provided by itself, or may be separately provided in addition to a shell layer of n-type semiconductor as shown in FIG. 8.

Subsequently, as shown in FIG. 1F, the gap between the quantum-dot nanowires 30 in the superlattice semiconductor layer 13 is filled with a resin 10 such as, for example, BCB (benzocyclobutene). In addition, for the resin 10, the same material as the barrier layers 20 may be used, or semiconductor materials and wavelength conversion materials which are able to absorb solar light may be used unlike the barrier layers 20.

The resin 10 is subjected to partial etching with the use of, for example, RIE (Reactive Ion Etching) method with CHF3/O2 plasma. The region opened by the partial etching is provided to make contact with an external circuit. The difference in selectivity allows the resin 10 to be preferentially etched.

Finally, the p-type semiconductor layer 15 is formed as shown in FIG. 1H. The p-type electrode 16, and further, the n-type electrode 11 are formed to form the solar cell 100 including a superlattice structure. For example, an AuGeNi/Au material can be used for both the p-type electrode 16 and the n-type electrode 11. The electrodes can be formed by, for example, electron-beam deposition.

A window layer or a contact layer may be provided on the p-type semiconductor layer 15. In addition, a highly n-type doped BSF layer may be used on the n-type semiconductor layer 1. The core layer 5 may also serve as a BSF layer, or a BSF layer may be used between the core layer 5 and the n-type semiconductor layer 1.

While the method for manufacturing the solar cell 100 has been described above, the present invention is not to be considered limited to these manufacturing methods or configurations. For example, while the n-type semiconductor layer 1 is used in the manufacturing method according to the first embodiment, a p-type semiconductor may be used as a substrate. In such a case, an n-type semiconductor may be used in place of the p-type semiconductor layer 15. Furthermore, the quantum-dot nanowires 30 may be n-type doped.

For example, Si and Zn may be used respectively as the n-type dopant and the p-type dopant. Other n-type dopants include, for example, S, Se, Sn, Te, and C.

While electron lithography is used for the SiO₂ patterning in the manufacturing method according to the first embodiment, the SiO₂ pattern can be also formed by other approaches. For example, nanoimprint and photolithography may be used for the patterning. The use of these approaches is suitable for mass production at low cost.

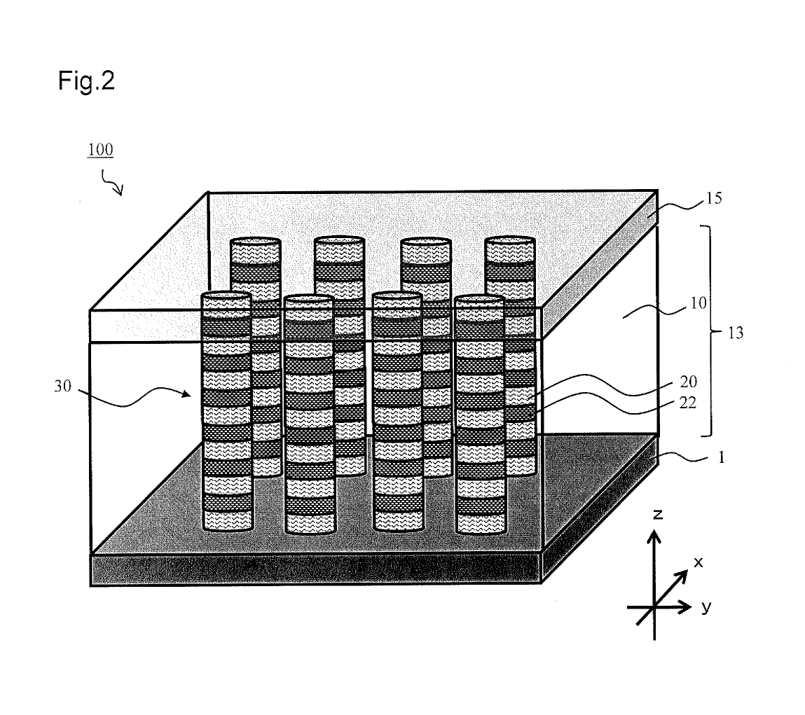

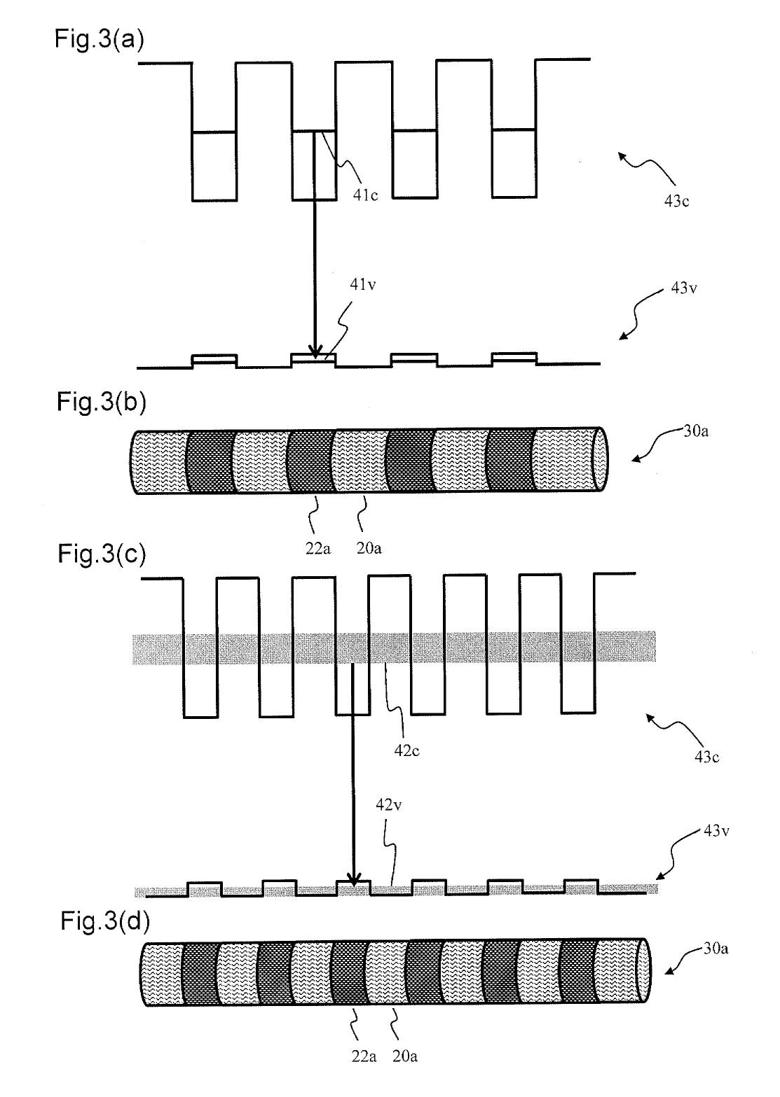

Next, a configuration of the solar cell 100 including the superlattice semiconductor layer 13 according to the first embodiment of the present invention will be described with reference to FIGS. 2 and 3A to 3D.

FIG. 2 is a diagram illustrating the configuration of a solar cell according to the first embodiment of the present invention

FIGS. 3A to 3D are diagrams illustrating the relationship between the quantum-dot to quantum-dot distance in a quantum-dot nanowire according to the first embodiment of the present invention and the band structure of the dot.

It is to be noted that while the structures of the shell layer 14, etc. are omitted in FIGS. 2 and 3A to 3D for the explanation, the same applies in the case of including the shell layer 14.

As shown in FIG. 2, a superlattice semiconductor layer 13 that has a plurality of quantum-dot nanowires 30 equal in diameter uniformly arranged, for example, at an area density of 4 nanowires/μm² or more is formed, and provided in a solar cell 100, thereby succeeding in efficiently absorbing the solar light spectrum.

It is to be noted that the area density of quantum dots also in consideration of the height of the quantum-dot nanowire 30 is extremely important in addition to the area density, in semiconductor devices such as solar cells. The area density also in consideration of the height direction is obtained by multiplying the quantum dot area density per 1 cm² layer by the number of quantum-dot layers, which is preferably 2.0×10¹⁰/cm² or more, further preferably 1.0×10¹¹/cm² or more, further preferably 1.0×10¹¹/cm² to 1.0×10¹³/cm², and further preferably 5.0×10¹¹/cm² to 1.0×10¹³/cm².

At this area density, solar light can be absorbed sufficiently, and the solar cell 100 can be achieved which has extremely high energy conversion efficiency.

In addition, it is preferable to shorten the distance between the quantum-dot layers 22 in the quantum-dot nanowire 30, because minibands 42c and 42v are formed between the quantum dots to make carriers likely to pass between the minibands 42c and 42v.

FIG. 3A is a band schematic diagram in the case of a long quantum-dot to quantum-dot distance (FIG. 3B), whereas FIG. 3C is a band schematic diagram in the case of a short quantum-dot to quantum-dot distance (FIG. 3D).

When the distance between the quantum-dot layers 22 in the quantum-dot nanowire 30 is long as shown in FIG. 3B, there are quantum energy levels 41c and 41v independently as shown in FIG. 3A. On the other hand, when the distance between the quantum-dot layers 22 in the quantum-dot nanowire 30 is short as shown in FIG. 3D, as shown in FIG. 3C, the wave functions of adjacent quantum dots overlap with each other, and the quantum energy levels 41c and 41v couple to form minibands 42c and 42v (shaded areas in FIG. 3C). The formation of the minibands 42c and 42v easily induces carrier transfer, and makes radiative recombination less likely to be induced, thus increasing the energy conversion efficiency of the solar cell 100.

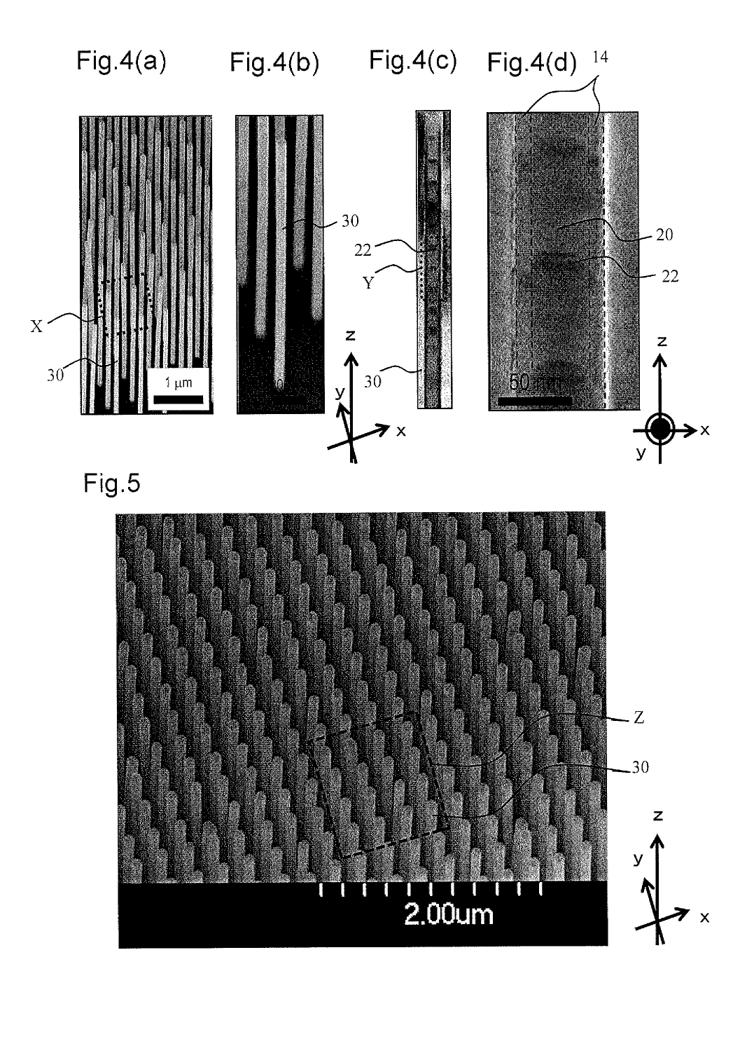

For example, in the case of using a structure shown in FIG. 4A to 4D (described later), shifting of the PL emission spectrum to longer wavelengths was observed when the distance between the quantum-dot layers 22 was 5 nm or less, and thus, the minibands 42c and 42v are considered to be formed.

Next, methods for evaluating the quantum-dot nanowire 30 will be described.

Information on the quantum-dot layers 22 in the quantum-dot nanowire 30, such as size, uniformity, dislocation, and arrangement in the z direction can be confirmed by TEM (Transmission Electron Microscopy) observation, or by SEM (Scanning Electron Microscopy) observation.

The n-type dopant concentration in the quantum-dot nanowire 30 can be confirmed by SIMS (Secondary Ion Mass Spectrometry).

The total number of states for the quantum energy level in the quantum-dot nanowire 30 can be found by using PES (Photoelectron Spectroscopy), UPS (Ultraviolet Photoelectron Spectroscopy), XPS (X-ray Photoelectron Spectroscopy), or the like.

In addition, it is also possible to confirm the area density and stacking number of quantum-dot layers 22, which were obtained by the TEM observation, and the number of quantum energy levels by PL (Photo Luminescence) measurement, and calculate the total number of states thereof.

The degree of strain in the quantum-dot nanowire is defined by the percentage of a deviation of the lattice constant of quantum-dot layer from the lattice constant of bulk. While the degree of strain can be also evaluated by TEM high-resolution observation, the PL emission intensity may be also used for the evaluation of the degree of strain in some cases because the degree of strain also significantly correlates with the PL emission intensity.

In the case of the solar cell 100 formed in accordance with the manufacturing process described above, for example, the number of quantum energy levels can be confirmed by PL measurement for measuring an emission spectrum from the solar cell 100. For example, an Ar laser and a Ge photodetector are used respectively as an excitation light source and a detector to measure the PL emission intensity of the quantum-dot nanowire 30 at 11 K. The calculation of energy (photon energy) corresponding to an emission band of the measured emission spectrum can confirm how the quantum energy level is formed. The forbidden bandwidth of the barrier layer 20 can be also confirmed. Furthermore, an optical absorption spectrum may be measured to confirm the formation of a quantum energy level.

### 4. Quantum Dot Nanowire Stacking Experiment and PL Measurement Experiment

Next, the results of a stacking experiment and a PL measurement experiment on the quantum-dot nanowire 30 according to the first embodiment of the present invention will be described with reference to FIGS. 4A through 6.

FIGS. 4A to 4D are SEM and TEM observation images of quantum-dot nanowires according to the first embodiment.

FIG. 4A is a SEM observation image of the quantum-dot nanowires 30 according to the first embodiment, where a section X is a 1 μm square area.

FIG. 4B is a partially enlarged view of FIG. 4A. FIG. 4C is a TEM observation image of the quantum-dot nanowire 30 according to the first embodiment, and FIG. 4D is an enlarged view of a section Y in FIG. 4C.

From the SEM image in FIG. 4A, it can be confirmed that four quantum-dot nanowires 30 are formed per 1 μm square, and it is determined that the superlattice structure in FIGS. 4A to 4D has an area density of at least 4 nanowires/μm².

On the other hand, it is determined from the SEM image in FIG. 4B that the quantum-dot nanowires 30 extend in the z direction, stacked substantially perpendicular to the substrate surface, and nearly uniform in diameter in the z direction. In addition, it is determined from the TEM images in FIGS. 4C and 4D that the quantum-dot layers 22 of 40 nm in diameter and 7 nm in height are formed at regular intervals while keeping the uniform size, without any dislocations observed.

The structure with both right and left sides of the quantum-dot layer 22 coated with several nm are observed as indicated by dotted lines in FIG. 4D, because the quantum-dot nanowire 30 formed is coated with the shell layer 14. Core-shell growth has not been confirmed in which the shell layer 14 is grown on both right and left sides at a stage of forming the quantum-dot nanowire 30, and it is determined that axial growth is produced in which the quantum-dot nanowire 30 is grown only in a vertical direction. Accordingly, it is determined that the uniform quantum-dot layers 22 are formed over the entire quantum-dot nanowires 30.

In addition, even on the same substrate, a superlattice structure in which the quantum-dot nanowires 30 of two types of diameters or densities are arranged with a high degree of precision on different plane regions on the same substrate can be prepared by changing the diameters or density of the openings 35 formed in the mask layer 2.

FIG. 5 is a SEM observation image of the superlattice structure according to the first embodiment of the present invention.

The Z section is an area of 1 μm square, it can be confirmed that sixteen quantum-dot nanowires 30 are formed per 1 μm square, and it is determined that the superlattice structure in FIG. 5 has an area density of at least 16 nanowires/pmt. In addition, it is determined that the quantum-dot nanowires 30 extend in the z direction, stacked substantially perpendicular to the substrate surface, and nearly uniform in diameter in the z direction.

In addition, a superlattice structure in which the quantum-dot nanowires 30 of at least two types of diameters or densities are arranged with a high degree of precision on different plane regions on the same substrate can be prepared by changing the diameters or density of the openings 35.

From the results mentioned above, it is determined that with the quantum-dot nanowires 30 according to the present invention, a superlattice structure is achieved which keeps the quantum dot layers 22 uniform in size even in highly-stacked cases, and has the quantum-dot nanowires 30 arranged with a high degree of precision.

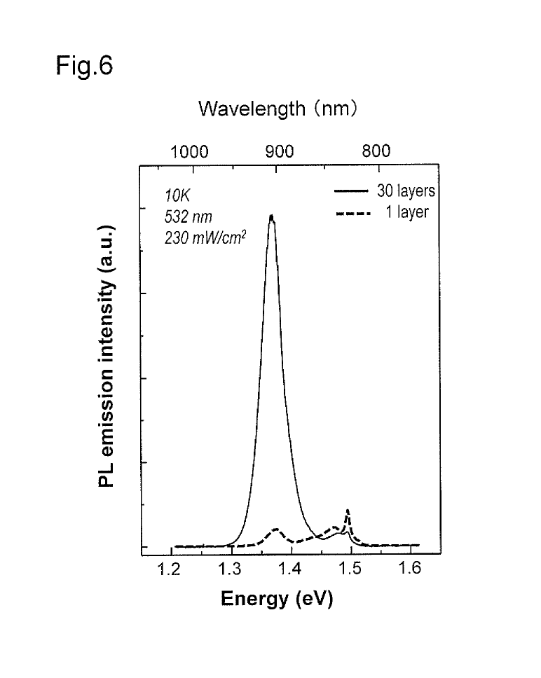

FIG. 6 is a PL measurement result of the superlattice structure according to the first embodiment of the present invention.

The horizontal axis in FIG. 6 indicates light energy (eV) (or the corresponding wavelength (nm)), whereas the vertical axis therein indicates an observed PL (photoluminescence) emission intensity (astronomical unit).

The dashed line graph in FIG. 6 shows the dependence of the PL intensity of a single-layer quantum-dot layer on the energy (eV). The solid line graph in FIG. 6 shows the dependence of the PL intensity of a thirty-layer stacked quantum-dot layer on the energy (eV). The temperature for the measurement is 10 K. The luminescence near a wavelength of 900 nm is attributed to the quantum dots.

From the result in FIG. 6, it is determined that the emission intensity of the thirty layers of quantum dots prepared is about thirty times as high as compared with the emission intensity of the single-layer quantum dot.

In common growth (for example, SK growth forming quantum dots from film growth), there is a tendency to gradually increase strain as quantum-dot layers 22 are stacked, and the PL emission intensity is thus not proportional to the stacking number of quantum-dot layers 22, and lower than that for the stacking number of quantum-dot layers 22. However, in the result of FIG. 6, the PL emission intensity of a quantum-dot nanowire 30 with thirty quantum-dot layers 22 stacked is 30 times as high as that of a quantum-dot nanowire 30 with only one quantum-dot layer 22 stacked, and is approximately proportional to the stacking number of quantum-dot layers 22.

In addition, from the fact that there is no substantial change in full width at half maximum or emission peak energy level from a spectral resolution, it is determined that the uniformity is not damaged with high crystal quality even when the thirty layers are stacked. Accordingly, it is determined that high-quality quantum-dot layers 22 with high uniformity are achieved.

[First Modification Example of First Embodiment]

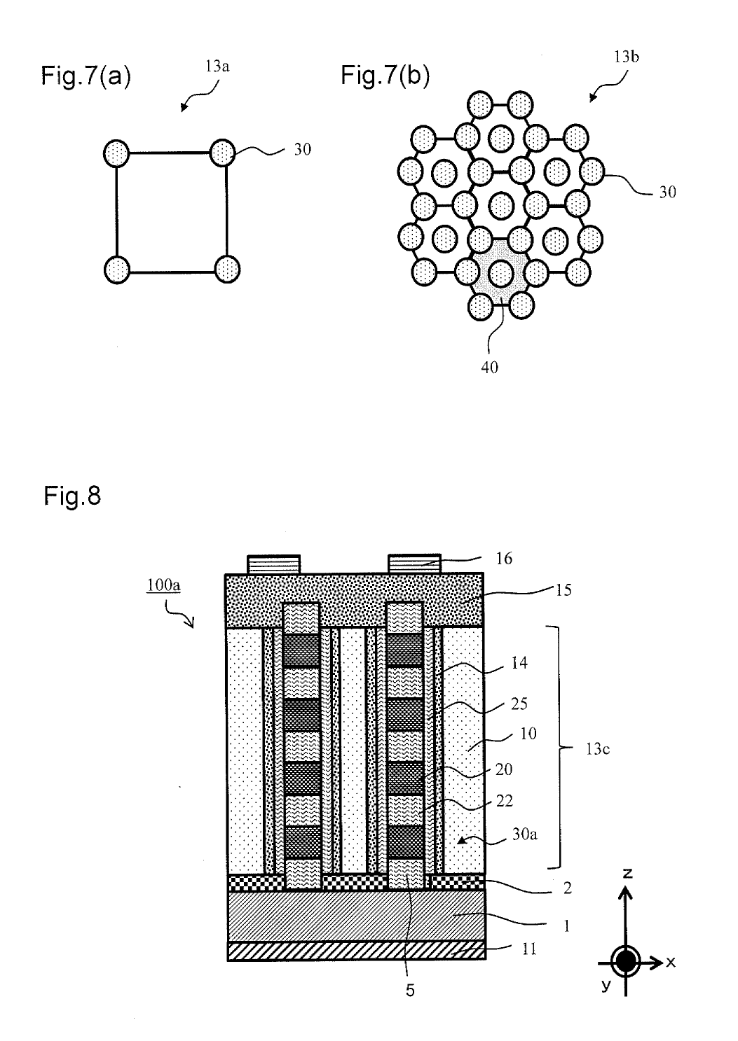

Next, modification examples 13a and 13b of the superlattice semiconductor structure 13 according to the first embodiment of the present invention will be described with reference to FIGS. 7A and 7B.

FIGS. 7A and 7B are plan views illustrating configurations according to a modification example of the superlattice structure according to the first embodiment of the present invention.

FIG. 7A is the superlattice semiconductor layer 13a which have quantum-dot nanowires 30 arranged in a square form on a plane region, whereas FIG. 7B is the superlattice semiconductor layer 13b which have quantum-dot nanowires 30 arranged in a regular hexagonal form on a plane region.

As shown in FIG. 7A, when the quantum-dot nanowires 30 are arranged alternately with a constant repeating period, the plurality of quantum-dot nanowires 30 influence one another in a synergistic manner, and when the arrangement is applied to a solar cell or the like, optical confinement between the quantum-dot nanowires 30 will be induced efficiently, and solar light can be absorbed efficiently. In particular, when the interval between the quantum-dot nanowires 30 is smaller than wavelengths of solar light (for example, 200 nm or less), efficient absorption is considered more likely to be achieved due to the periodic structures of the quantum-dot nanowires 30, with reduced influences such as reflection of solar light. In addition, solar light can be effectively absorbed, and thus, the amounts of materials used can be preferably reduced dramatically as compared with thin-film quantum-dot structures formed by SK growth or the like, thereby leading to a reduction in cost.

In addition, the quantum-dot nanowires 30 arranged in a regular hexagonal form as shown in FIG. 7B makes it possible to form a closest-packing quantum-dot nanowire array. It is to be noted that a shaded region 40 in the figure represents a repeating minimum unit.

[Second Modification Example of First Embodiment]

Next, a configuration of a modification example 100a of the solar cell 100 according to the first embodiment of the present invention will be described with reference to FIG. 8.

FIG. 8 is a cross-sectional view illustrating a structure according to a modification example of the solar cell according to the first embodiment of the present invention.

It is to be noted that sections similar and corresponding to those of the solar cell 100 shown in FIGS. 1A to 1H are denoted by the same reference numerals, and descriptions of the sections will be skipped. The same applies to other embodiments.

As shown in FIG. 8, a shell layer of the solar cell 100a has a double structure of a shell layer 14 and shell layer 25. The shell layer 25 has the same effect as the shell layer 14, and additionally, for example, in the case of an n-type semiconductor, has the advantage of being able to efficiently flow carriers into an n-type semiconductor layer 1. As materials for the double structure, for example, the shell layer 25 may be an n-type semiconductor, whereas the shell layer 14 may be a p-type semiconductor. This structure allows electrons generated by photoexcitation to flow into the shell layer 25, pass through a core layer 5, and efficiently flow through the n-type semiconductor layer 1 to an external circuit, and allows holes generated by photoexcitation to flow into the shell layer 14, and efficiently flow through a p-type semiconductor layer 15 to an external circuit, and the solar cell 100a thus achieves a high energy conversion efficiency. Alternatively, the shell layer 14 may be an n-type semiconductor, whereas the shell layer 25 may be a p-type semiconductor. Furthermore, for the purpose of surface stability, another layer may be added to the shell layers 14 and 25 to provide a structure of three or more layers.

### Second Embodiment

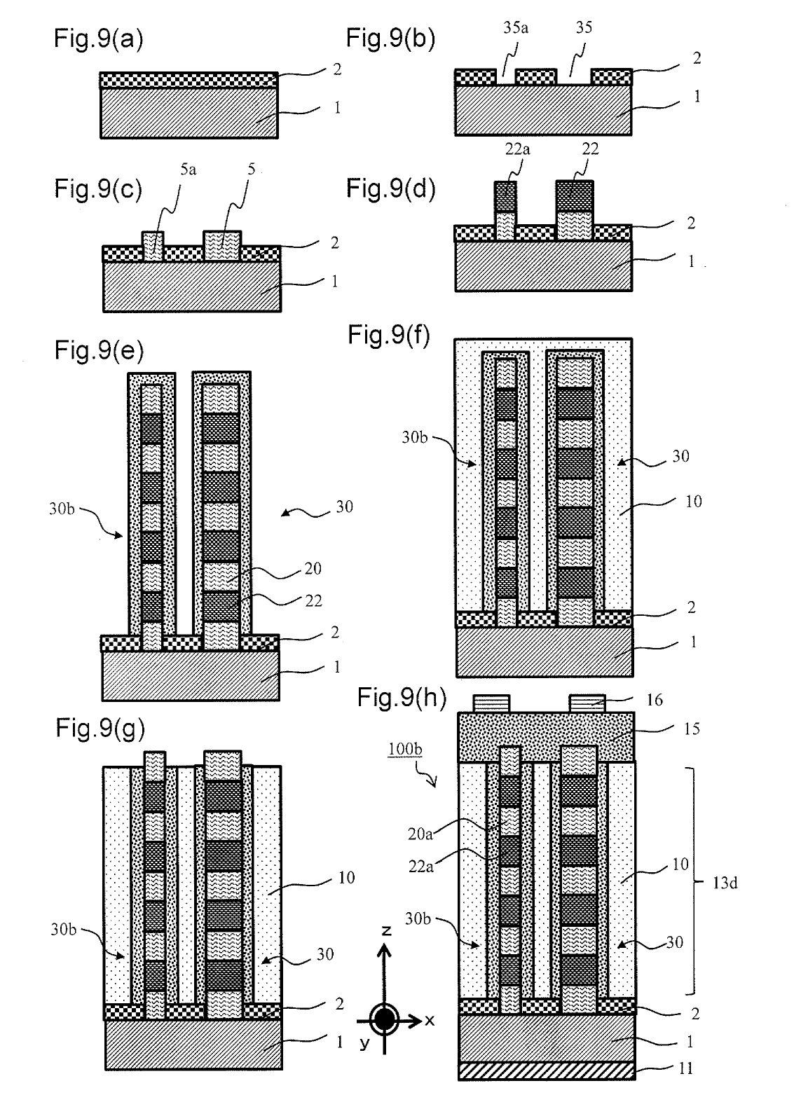

Next, a configuration of a solar cell 100b according to a second embodiment of the present invention will be described with reference to FIGS. 9A to 9H.

FIGS. 9A to 9H are diagrams illustrating a process for manufacturing a solar cell including a superlattice structure according to the second embodiment of the present invention.

As shown in FIGS. 9E to 9H, in the process for manufacturing the solar cell 100b, in a region in the x-y plane on the order of a solar light wavelength (for example, 500 nm) or less, further preferably in a region in the x-y plane on the order of a ultraviolet light wavelength (for example, 300 nm) or less, quantum-dot nanowires 30 and 30a of different types of diameters are formed, where quantum-dot layers 22 and 22a that are the same in size, material, and mixed crystal ratio are formed in the z direction.

As a specific manufacturing method, openings 35 and 35a of different diameters (sizes) are formed in advance in a mask layer 2 as shown in FIG. 9B, core layers 5 and 5a corresponding to the openings 35 and 35a are formed as shown in FIG. 9C, and quantum-dot layers 22 and 22a and barrier layers 20 and 20a are then alternately stacked respectively. It is to be noted that the openings 35 and 35a are preferably formed to have sizes not more than a short wavelength of solar light (for example, 500 nm), and more preferably formed to have sizes not more than a ultraviolet wavelength (for example, 300 nm).

This configuration can efficiently absorb solar light without wasting the solar light.

In the case of this structure, the lengths of the quantum dots (for example, quantum-dot layers 22 (22a)) in the quantum-dot nanowires 30 (30a) with different diameters can be each changed in the stacking direction (z direction) by appropriately changing not only the growth conditions such as temperatures, pressures, and proportions of raw materials, but also the interval between the quantum-dot nanowires 30 (30a), the area ratio of the openings 35 (35a) in the mask layer 2, and the diameters of the openings 35 (35a).

This structure achieves quantum-dot layers of different sizes, and due to the different quantum energy levels of the quantum-dot layers, a wide wavelength range of the solar light spectrum can be absorbed efficiently, thus improving the energy conversion efficiency of the solar cell 100 b.

[First Modification Example of Second Embodiment]

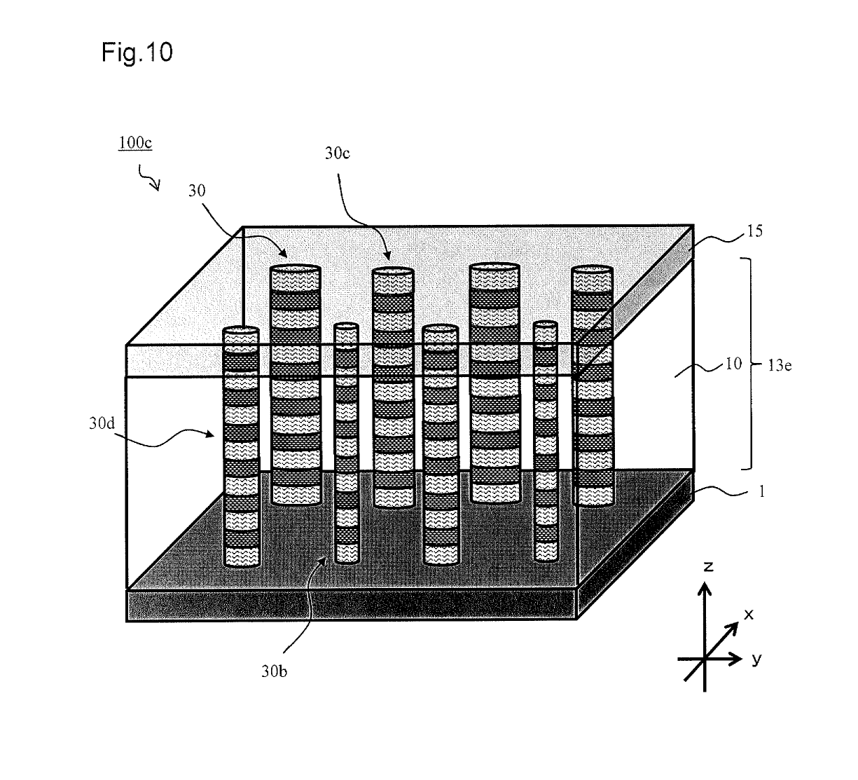

Next, a configuration of a modification example 100c of the solar cell according to the second embodiment of the present invention will be described with reference to FIG. 10.

FIG. 10 is a diagram illustrating a structure according to a modification example of the solar cell according to the second embodiment of the present invention.

As shown in FIG. 10, quantum-dot nanowires 30 and 30b to 30d that include quantum-dot layers of the same length in the stacking direction (z direction) in each quantum-dot nanowire, and respectively have four different types of diameters are arranged in a region in the x-y plane, which has an area on the order of a solar light wavelength, so that the solar light spectrum can be absorbed efficiently.

According to theoretical estimations, a solar cell has a theoretical maximum efficiency of 63% in the case of using one type of quantum dot, a theoretical maximum efficiency of 70% in the case of using two types of quantum dots, a theoretical maximum efficiency of 73% in the case of using three types of quantum dots, and a theoretical maximum efficiency of 75% in the case of using four types of quantum dots. On the other hand, the increase in efficiency is significantly slowed in the case of five or more types of quantum dots. Thus, one to four types of quantum dots achieve high potentials, and four types of quantum dots achieve the highest potential.

The theoretical maximum efficiency varies depending on light collection rates and materials, and for example, when GaAs (bandgap: 1.4 eV) is used for the barrier layers, the theoretical maximum conversion efficiency is 55% under 1000 times light collection in the case of using four types of quantum dots, whereas the theoretical maximum conversion efficiency is 52% under 1000 times light collection (36% under 1000 times light collection at the GaAs single junction) in the case of using one type of quantum dot. In addition, the theoretical maximum conversion efficiency is 39% under no light collection in the case of four types of quantum dots, whereas the theoretical maximum conversion efficiency is 37% under no light collection (31% under no light collection at the GaAs single junction) in the case of using one type of quantum dot.

In addition, when Al_{0.45}Ga_{0.55}As (bandgap: 2.0 eV) is used for the barrier layers, the theoretical maximum conversion efficiency is 66% under 1000 times light collection in the case of using four types of quantum dots, whereas the theoretical maximum conversion efficiency is 57% under 1000 times light collection (27% under 1000 times light collection at the Al_{0.45}Ga_{0.55} single junction) in the case of using one type of quantum dot. In addition, the theoretical maximum conversion efficiency is 52% under no light collection in the case of four types of quantum dots, whereas the theoretical maximum conversion efficiency is 45% under no light collection (25% under no light collection at the Al_{0.45}Ga_{0.55}As single junction) in the case of using one type of quantum dot.

As described above, the quantum-dot solar cell has a high potential as compared with a single-junction solar cell, and the theoretical maximum conversion efficiency is increased as there are more types of quantum dots, and as there is a higher degree of light collection.

Therefore, in order to efficiently absorb the solar light spectrum, it is preferable to arrange a plurality of types of quantum dots (different in size, material, or mixed crystal ratio) in a region in the x-y plane. This configuration causes the quantum-dot layers of different sizes to efficiently absorb different wavelengths of solar light, and the application of this structure to a solar cell thus improves the energy conversion efficiency.

As for the types of quantum dots, one type of quantum dot is preferably used, two types of quantum dots are further preferably used, three types of quantum dots are further preferably used, and four types of quantum dots are further preferably used.

In addition, as for the types of quantum-dot nanowire diameters, there is preferably one type of nanowires which are substantially the same in diameter, there are further preferably two types of nanowires, there are further preferably three types of nanowires, and there are further preferably four types of nanowires.

Moreover, there are preferably two types of nanowires of substantially the same diameter per 1 μm², further preferably three types of nanowires per 1 μm², and further preferably four types of nanowires per 1 μm².

It is to be noted that the “type” of the quantum dot includes the size, material, and mixed crystal ratio (composition ratio) of the quantum dot. While the length in the stacking direction is cited herein as an example of the “size” of the quantum dot, the “size” may be the length in a direction other than the z direction (for example, the length in the x or y direction), an area, or a volume. The “size” of the quantum dot can be changed by changing not only the height in the stacking direction of the quantum-dot layers 22, but also the diameters of the quantum-dot nanowires. Further, a configuration may be adopted by not only changing the size in the region in the x-y plane and in the z direction, but also appropriately changing the lengths of the quantum-dot layers in the x direction, the y direction, and the z direction, depending on the desired number of quantum energy levels.

The formation of the quantum-dot nanowires 30 and 30b to 30d with different diameters in a region in the x-y plane herein means that, for example, in the case of wishing to form the quantum-dot nanowires 30 and 30b to 30d with four types of diameters, the quantum-dot nanowires 30 and 30b to 30d with at least the four types of diameters are formed in the region in the x-y plane.

[Second and Third Modification Examples of Second Embodiment]

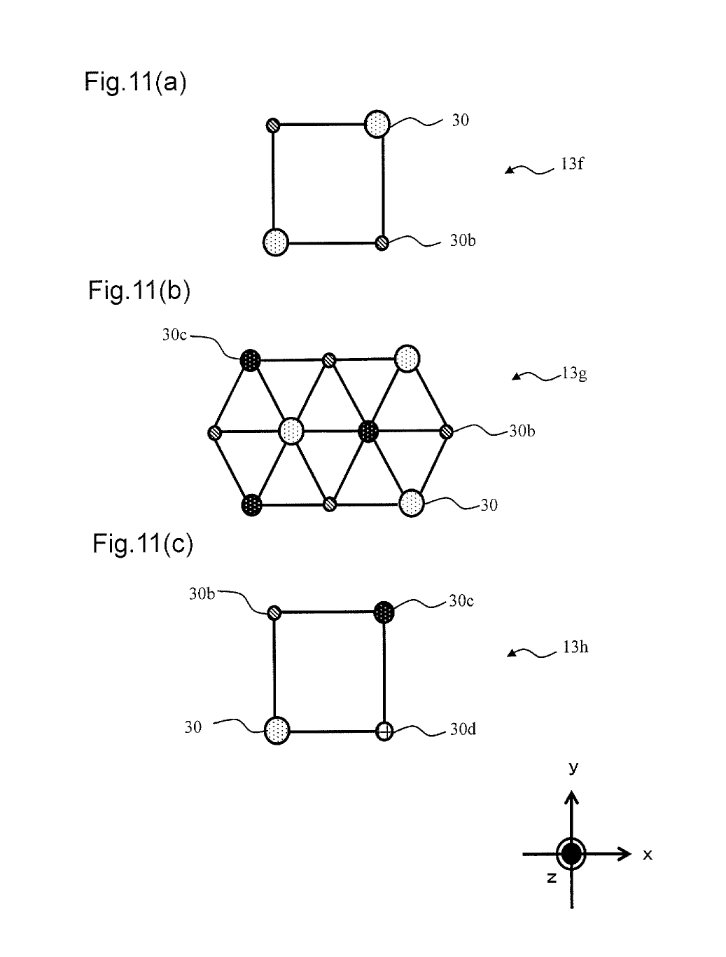

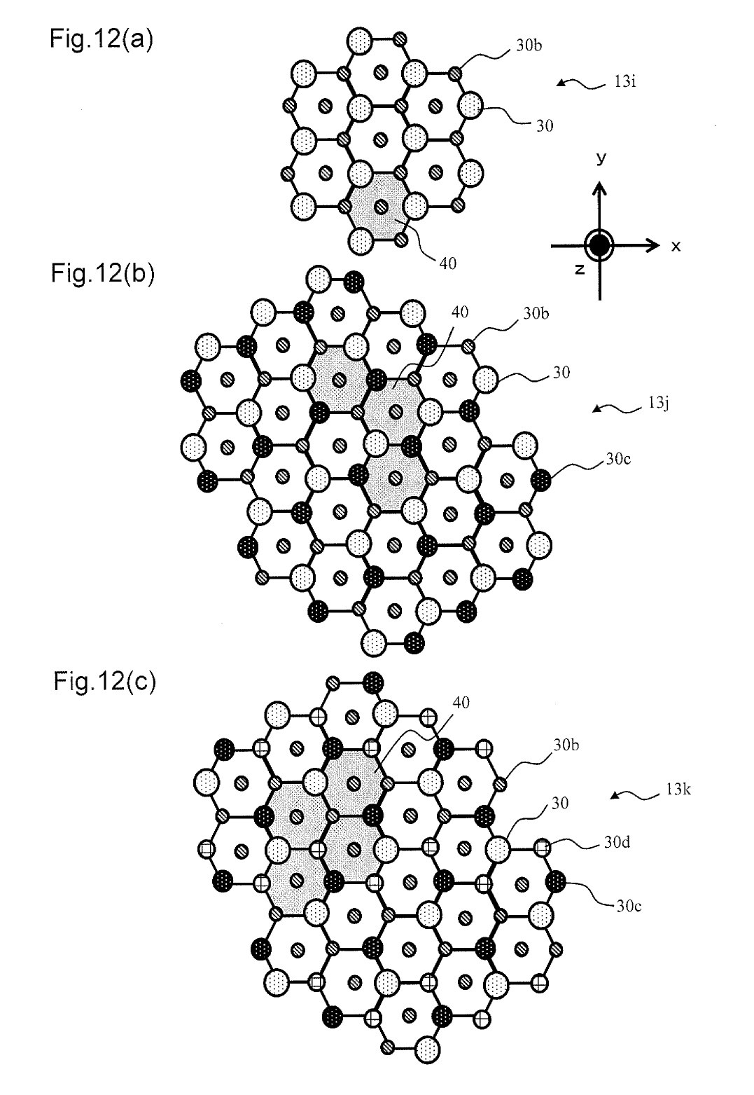

Next, configurations of second modification examples 13f to 13h and third modification examples 13i to 13k of the second embodiment of the present invention will be described with reference to FIGS. 11A to 11C and FIGS. 12A to 12C.

FIGS. 11A to 11C are plan views illustrating configurations according to a second modification example of the second embodiment of the present invention.

FIGS. 12A to 12C are plan views illustrating configurations according to a third modification example of the second embodiment of the present invention.

While FIG. 10 shows a diagram schematically illustrating a structure in which quantum-dot nanowires with four types of diameters are evenly arranged in a square form (the evenness in a square form refers to the centers of the circles arranged in a square form when the quantum-dot nanowires are viewed from the z direction), FIGS. 11A to 11C show diagrams schematically illustrating quantum-dot nanowires alternately arranged in a region in the x-y plane, for each type of quantum-dot nanowire.

FIGS. 11A to 11C are respectively pattern diagrams of two, three, and four types of quantum-dot nanowires arranged.

As shown in FIGS. 11A to 11C, in the case of using a plurality of types of quantum-dot nanowires, it is not always necessary to equalize all of the intervals between the quantum-dot nanowires, and the intervals between the quantum-dot nanowires may be shifted to arrange the quantum-dot nanowire. This arrangement can control stacking of quantum dots and quantum-dot nanowires in some cases. More specifically, for example, the lengths of the quantum dots in the stacking direction (z direction) can be controlled. However, in such a case, it is preferable to arrange quantum-dot nanowires with a constant repeating period for a constant repeating minimum unit, in order to achieve uniform stacking conditions, and efficiently absorb solar light.

FIGS. 12A, 12B, and 12C are respectively plan views illustrating the configurations of the superlattice semiconductor layers 13i, 13j, and 13k including two types (30 and 30b), three types (30, 30b, and 30c), and four types (30 and 30 b to 30d) quantum-dot nanowires of different diameters.

The two to four multiple types of quantum-dot nanowires 30 and 30b to 30d of different diameters arranged in a regular hexagonal form as shown in FIGS. 12A to 12C makes it possible to form a closest-packing quantum-dot nanowire array. Shaded region 40 in FIGS. 12A to 12C represent repeating minimum units. It is to be noted that in the case of arranging two or more multiple types of quantum dots with different diameters, for example, the quantum-dot nanowire with the smallest diameter (the quantum-dot nanowire 30b in FIGS. 12A to 12C) is placed in the center of the regular hexagon. This is because, due to the fact that the quantum-dot layers included in the quantum-dot nanowire with the smallest diameter have the smallest volume (cross section), there is a need to increase the volume of the quantum-dot layers in order to sufficiently absorb solar light. This arrangement can achieve an increase in the density of the superlattice structure.

### Third Embodiment

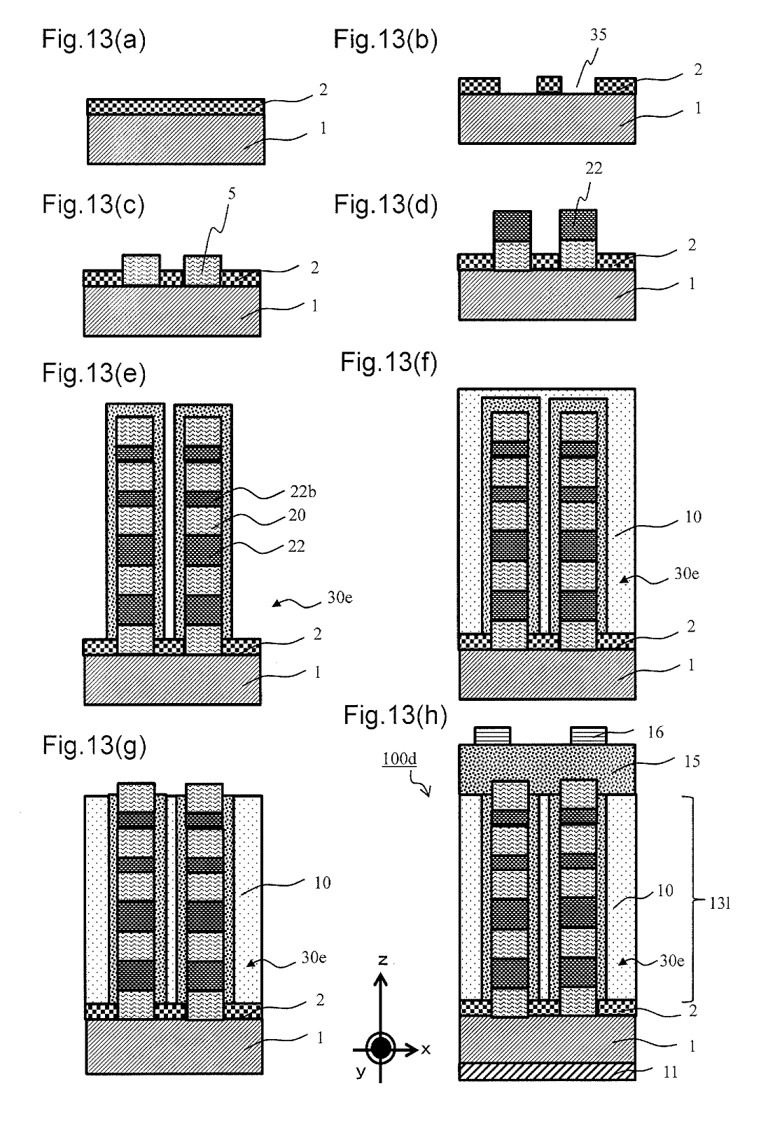

Next, a solar cell 100d including a superlattice semiconductor layer 13l according to a third embodiment of the present invention will be described with reference to FIGS. 13A to 13H.

FIGS. 13A to 13H are diagrams illustrating a process for manufacturing a solar cell including a superlattice structure according to the third embodiment of the present invention.

As shown in FIG. 13H, the solar cell 100d including quantum-dot nanowires has quantum-dot nanowires 30e arranged in an x-y in-plane region, where the quantum-dot nanowires 30e have quantum-dot layers 22 and 22b of the same diameter and different lengths in the z direction.

Specifically, as shown in FIGS. 13E to 13H, openings 35 in a mask layer 2 of SiO₂ are made equal in size, and the quantum-dot layers 22 and 22b of different lengths are stacked in the stacking direction of the quantum-dot nanowires 30e. The use of this approach can change the quantum-dot layers in size intentionally in a controllable manner, thus forming high-quality quantum-dot layers without any dislocations. In addition, the arrangement of the quantum-dot nanowires 30e including the quantum-dot layers 22 and 22b of multiple types of lengths in the stacking direction can form a variety of bandgaps, and thus makes it possible to efficiently absorb a wide wavelength range of the solar light spectrum. More specifically, the different types of quantum-dot layers absorb light of different wavelengths included in solar light, and the application of this structure to a solar cell thus improves the energy conversion efficiency.

### Fourth Embodiment

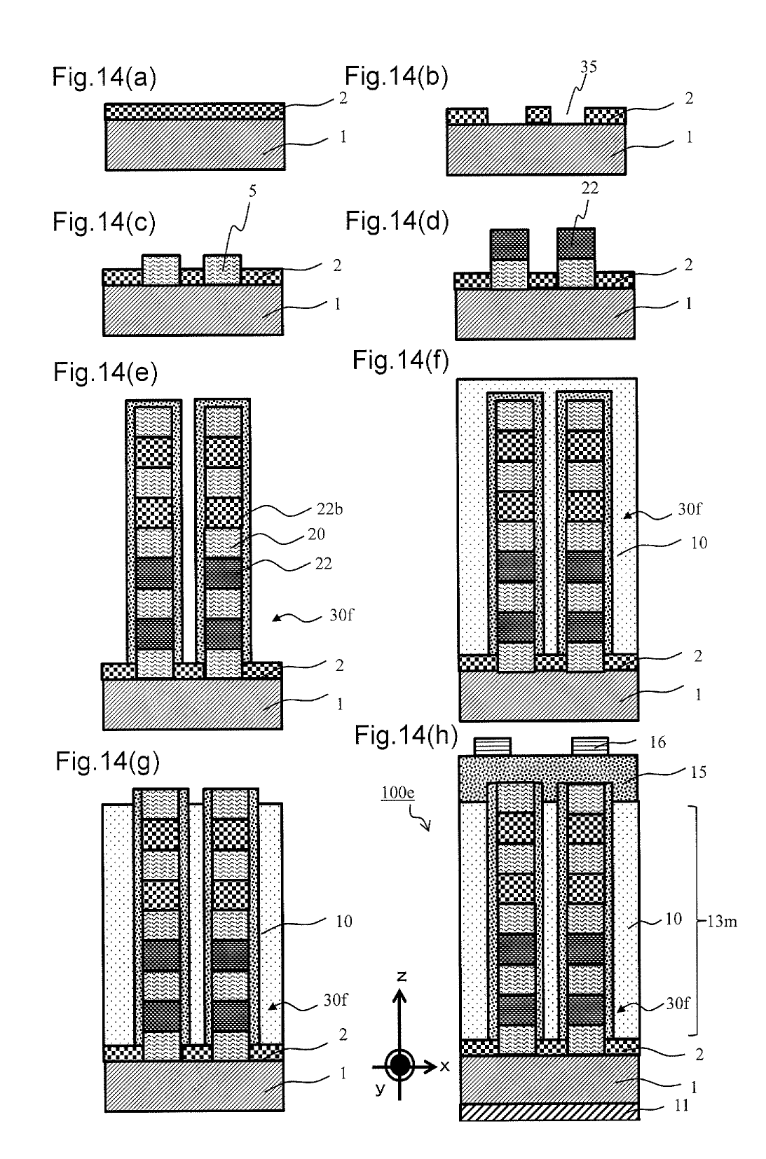

Next, a configuration of a solar cell 100e including a superlattice structure 13 m according to a fourth embodiment of the present invention will be described with reference to FIGS. 14A to 14H.

FIGS. 14A to 14H are diagrams illustrating a process for manufacturing a solar cell including a superlattice structure according to the fourth embodiment of the present invention.

As shown in FIG. 14H, the solar cell 100e according to the fourth embodiment have quantum-dot nanowires 30f of the same diameter arranged in an x-y in-plane region, where quantum-dot layers 22 and 22b are formed which have different materials or mixed crystal ratios in the z direction.

Specifically, as shown in FIGS. 14E to 14H, openings 35 in a mask layer 2 of SiO₂ are made equal in size, and the materials or mixed crystal ratios of the quantum-dot layers 22 and 22b are varied in the stacking direction of the quantum-dot nanowires 30f. This configuration can intentionally change the materials and mixed crystal ratios of the quantum-dot layers in a controllable manner, thus forming high-quality quantum-dot layers without any dislocations, and efficiently absorbing the solar light spectrum.

### Fifth Embodiment

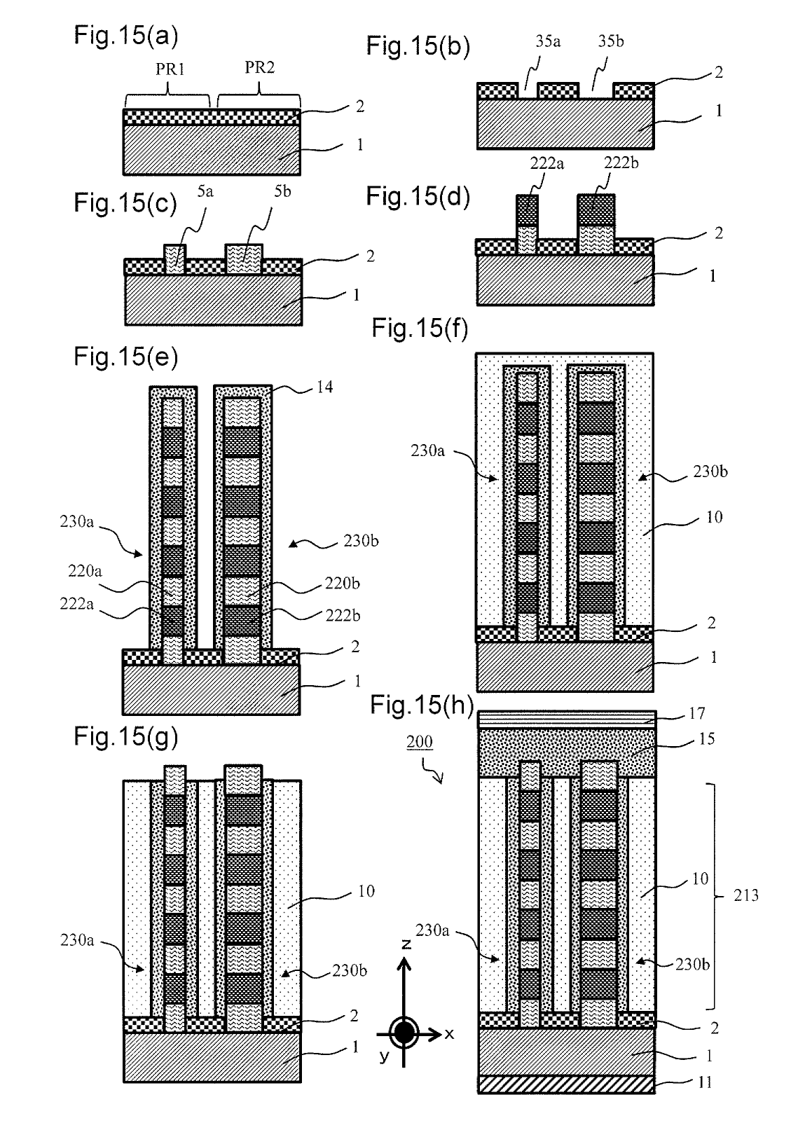

Next, a semiconductor light emitting device 200 according to a fifth embodiment of the present invention will be described with reference to FIG. 15A through 17.

It is to be noted that the following examples are by way of example, and respective materials such as substrates, buffer layers, quantum dots, dopants, electrodes for use in the semiconductor light emitting device 200 including the superlattice structure according to the present invention, cleaning agents, substrate treatment temperatures, manufacturing equipment for use in each process, etc. are not limited to the examples given herein. The same applies to other embodiments.

### <Structure of Semiconductor Light Emitting Device>

FIGS. 15A to 15H are diagrams illustrating a process for manufacturing a semiconductor light emitting device including a superlattice structure according to the fifth embodiment of the present invention.

The semiconductor light emitting device 200 according to the fifth embodiment includes an n-type semiconductor layer 1, a p-type semiconductor layer 15, and a superlattice semiconductor layer 213 sandwiched between the n-type semiconductor layer 1 and the p-type semiconductor layer 15.

The semiconductor light emitting device 200 will be described below.

The base material according to the present invention corresponds to the n-type semiconductor layer 1, whereas the superlattice structure according to the present invention corresponds to the superlattice semiconductor layer 213.

### 1. N-Type Semiconductor Layer and P-Type Semiconductor Layer

The n-type semiconductor layer 1 includes a semiconductor containing an n-type impurity, whereas the p-type semiconductor layer 15 includes a semiconductor containing a p-type impurity.

The n-type semiconductor layer 1 and the p-type semiconductor layer 15 sandwich the superlattice semiconductor layer 213 to constitute the semiconductor light emitting device 200, and can be formed by, for example, an MOCVD method or a sputtering method.

The p-type semiconductor layer 15 can be electrically connected to a transparent electrode 17, whereas the n-type semiconductor layer 1 can be electrically connected to an n-type electrode 11. Thus, the current injection through the transparent electrode 17 and the n-type electrode 11 from an external circuit makes it possible to produce luminescence from quantum-dot layers. In addition, a contact layer may be provided between the p-type semiconductor layer 15 and the transparent electrode 17, or between the n-type semiconductor layer 1 and the n-type electrode 11.

### 2. Superlattice Semiconductor Layer

The superlattice semiconductor layer 213 is sandwiched between the n-type semiconductor layer 1 and the p-type semiconductor layer 15. In addition, the superlattice semiconductor layer 213 has a superlattice structure of quantum-dot layers 222a (222b) and barrier layers 220a (220b) alternately stacked repeatedly. The superlattice semiconductor layer 213 in the semiconductor light emitting device 200 includes a plurality of quantum-dot nanowires 230a (230b).

The quantum-dot nanowire 230a (230b) according to the present invention is characterized in that the quantum-dot layers 222a (222b) in the superlattice semiconductor layer 213 are arranged in a high-quality and highly uniform fashion in a controllable manner also in terms of arrangement in the stacking direction (z direction). The quantum-dot layers 222a (222b) include a semiconductor material that has a narrower bandgap than the semiconductor material constituting the barrier layers 220a (220b), and have a quantum level on the conduction band side due to the quantum effect. Alternatively, the quantum level may be formed on the valence band side. In addition, the barrier layers 220a (220b) include a semiconductor material that has a wider bandgap than the semiconductor material constituting the quantum-dot layers 222a (222b), and form potential barriers around the quantum-dot layers 222a (222b).

In the fifth embodiment, for example, the quantum-dot layers 222a (222b) including InGaAs and the barrier layers 220a (220b) including GaAs can be used as the materials of the quantum-dot layers 222a (222b) and barrier layers 220a (220b) constituting the superlattice semiconductor layer 213. In addition, the quantum-dot layers 222a (222b) including InGaAs, the barrier layers 220a (220b) including AlGaAs, the quantum-dot layers 222a (222b) including InGaN, the barrier layers 220a (220b) including GaN, the quantum-dot layers 222a (222b) including InGaAsSb, and the barrier layers 220a (220b) including AlGaAsSb can be used. Besides, materials of InAs, GaAs, AlAs, InSb, GaSb, AlSb, InP, GaP, AlP, InN, GaN, AlN, Si, and SiGe, and mixed crystal materials thereof may be used. Furthermore, AlₓGa_{y}In_{1-x-y}As, AlₓGa_{y}In_{1-x-y}Sb_{z}As_{1-z}, AlₓGa_{y}In_{1-x-y}P, AlₓGa_{y}In_{1-x-y}N, etc., can be also used. Group III-V compound semiconductors, Group II-VI compound semiconductors, Group IV semiconductors, or mixed crystal materials thereof may be used other than listed above.

For example, when InAlGaN is used, it is possible to cover a wide range of wavelengths, because of the InN bandgap of 0.7 eV, the GaN bandgap of 3.4 eV and the AlN bandgap of 6.2 eV. The formation of the plurality of quantum-dot layers 222a (222b) using these materials on the same substrate makes it possible to prepare, for example, blue, green, and red LEDs on the same substrate.

The quantum-dot layers 222a (222b) including mixed crystals and the barrier layers 220a (220b) can, through appropriate changes in the element proportions of the mixed crystals, vary the quantum energy levels or the bandgaps of the barrier layers 220a (220b), and vary the valence band energy offset (the difference in valence band energy between the quantum-dot layer 222a (222b) and the barrier layer 220a (220b)).

In the fifth embodiment, as shown in FIG. 15, the quantum-dot nanowires 230a and 230b of different diameters can be formed in two types of plane regions PR1 and PR2 constituting a substrate surface of the n-type semiconductor layer 1.

This configuration causes the different types of quantum-dot layers 222a and 222b to emit light of different wavelengths, and the application of this superlattice semiconductor layer 213 to the semiconductor light emitting device 200 achieves a desired broadband emission spectrum. The major difference from the top-down approach using SK growth or etching technology is that the quantum-dot layers 222a and 222b according to the present invention can be changed in size in a controllable manner, and have a high luminous efficiency with fewer dislocations or defects. In addition, it is also not easy for the approach using VLS to achieve high-quality quantum dots, because there is a possibility that impurities will be mixed to decrease the luminous efficiency.

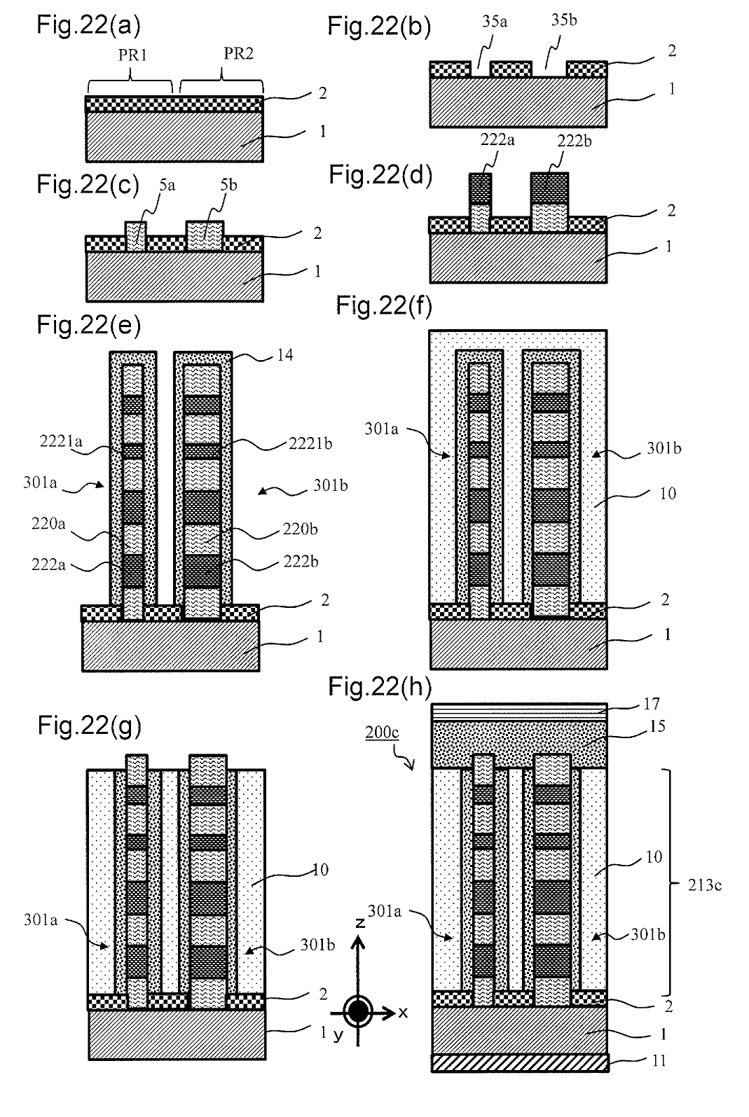

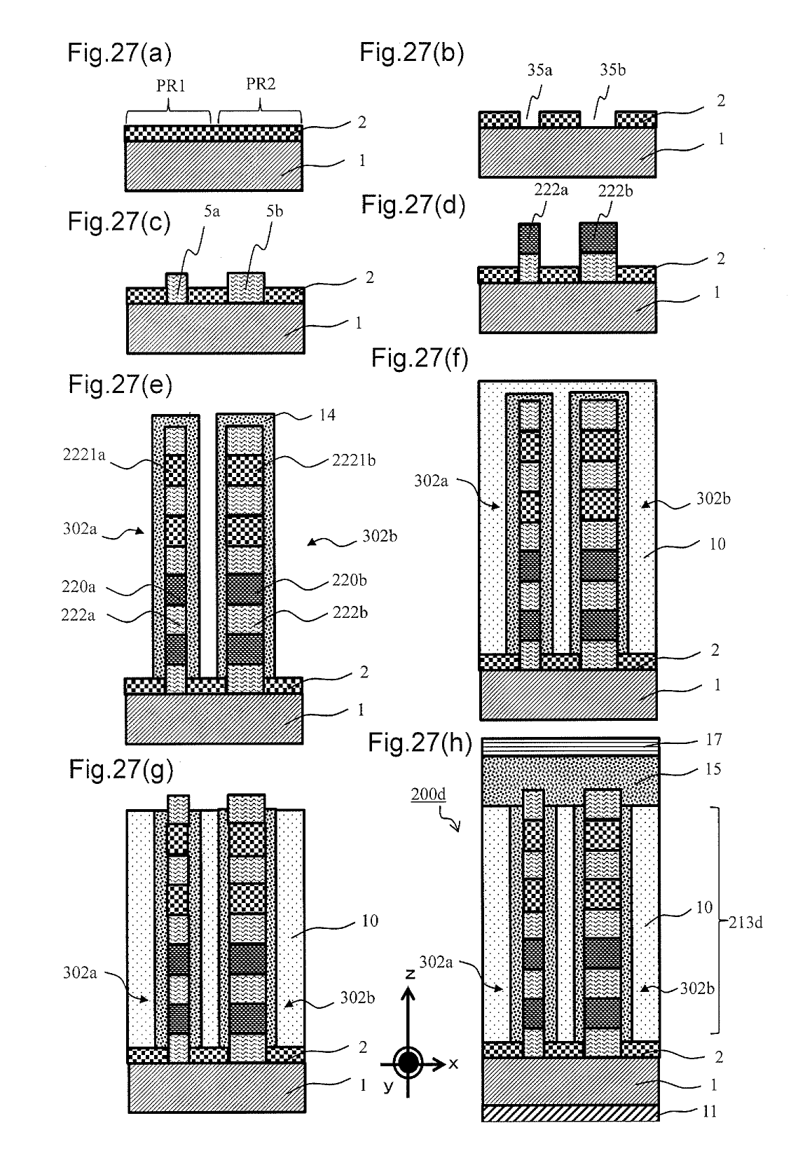

The use of the approach according to the present invention can form the quantum-dot layers 222a (222b) (the quantum dots in the z direction) included in the quantum-dot nanowire 230a (230b) in a controllable manner while relaxing strain, and the quantum-dot layers 222a (222b) included in the quantum-dot nanowire 230a (230b) may be changed in size in the stacking direction, material, or composition, as shown in FIGS. 22A to 22H (Sixth Embodiment described later) and FIGS. 27A to 27H (Seventh Embodiment described later). In this case, the quantum-dot nanowire 230a (230b) of different sizes may be formed in the plane, or the quantum-dot nanowire 230a (230b) of the same size may be formed therein.

Moreover, the proportions of elements incorporated in the quantum-dot layers 222a (222b) may be changed for each quantum-dot nanowire 230a (230b) by adjusting the diameters of the quantum-dot nanowire 230a (230b) and the interval between the quantum-dot nanowires 230a (230b).

As described above, the plurality of types of quantum-dot layers 222a (222b) formed can achieve an emission spectrum in a desired shape.

The dimensions of the quantum-dot layers 222a (222b) in the x direction, y direction, and z direction may be changed appropriately depending on the desired number of quantum energy levels. In the case of wishing to form quantum energy levels at the same energy value, for example, the quantum-dots may be made uniform in size in all of the x direction, y direction, and z direction. In the same plane region, the plurality of quantum-dot layers 222a (222b) (the quantum dots in the z direction) in the quantum-dot nanowire 230a (230b) all includes the same size and material, minibands are further formed by shortening the distance between the quantum dots to such an extent that the wave functions of adjacent quantum dots overlap with each other. As shown in FIG. 9, for example, in the conduction band, the lowest energy level in the miniband is different from the value of the quantum energy level obtained when the quantum dots are present in isolation (the wave functions of adjacent quantum dots fail to overlap with each other). These can be utilized to change the emission wavelength.

In addition, as shown in FIG. 15E, the quantum-dot nanowire 230a (230b) may have a coated structure (a shell layer 14). This is because the shell layer 14 provided for coating stabilizes the surface of the quantum-dot nanowire 230a (230b), and effectively reduces surface recombination. In addition, the shell layer 14 also has the advantage that carriers formed in the quantum-dot layers flow through the shell layer 14 to make it easy to inject the carriers. The shell layer 14 may have the same material as the n-type semiconductor layer 1 or the p-type semiconductor layer 15, or have a different material therefrom. In addition, as a layer for surface stabilization, another layer may be further provided on the outside of the shell layer 14.

It is to be noted that the shell layer 14 is preferably not excessively thick because the high-quality quantum-dot layers 222a (222b) can be highly stacked by relaxing strain in the x and y directions, while the shell layer 14 with a moderate thickness is preferred for the structure of the semiconductor light emitting device 200.

As shown in FIG. 15F, the gap between the quantum-dot nanowires 230a (230b) in the superlattice semiconductor layer 213 is filled with a resin 10 such as, for example, BCB (benzocyclobutene). In addition, the same material as the barrier layers 220a (220b) may be used for the resin 10.

It is to be noted that it is necessary to adopt a strain-relaxed structure in order to form the quantum-dot nanowires 230 (230b) of high quality. Therefore, the diameter of the quantum-dot nanowire 230a (230b) may be more preferably a critical diameter or smaller. The “critical diameter” herein refers to the diameter of the quantum-dot nanowire 230a (230b), with which the quantum-dot layers 222a (222b) can, without being strained, grow to the quantum-dot nanowire 230a (230b). In general, strain is relaxed as the diameter of the quantum-dot nanowire 230a (230b) is smaller, and it is thus possible to grow the quantum-dot nanowires 230a (230b) with almost no strain.

On the other hand, in the case of film formation by etching, because of close packing (infinite in length as compared with the size of the quantum-dot nanowire 230a (230b)) in a direction perpendicular to the stacking direction, strain is not able to be relaxed in the direction, and the quantum-dot layers 222a (222b) and the host material undergo a decrease in crystalline quality.

The diameter of the quantum-dot nanowire 230a (230b) is preferably 5 nm to 100 nm, and more preferably 5 nm to 70 nm. For example, when an In_{0.3}Ga_{0.7}As/GaAs material is used, the critical film thickness is approximately 100 nm because of the difference in lattice constant on the order of 2%, and the quantum-dot nanowire 230a (230b) may be configured to have a diameter of 100 nm or smaller. On the other hand, when the diameter is smaller than 5 nm, the control will be hard.

The quantum-dot nanowires 230a (230b) in the same plane region are preferably formed at an interval (the interval of the gap between the two quantum-dot nanowires 230a (230b)) of 30 nm to 500 nm. The arrangement of quantum dots at an interval of 500 nm or less can achieve a sufficiently high emission intensity.

However, the interval of 30 nm or less between the quantum-dot nanowires has a possibility of making it hard to form the quantum-dot nanowires 230a (230b).

As other structure, a light reflection layer, a current diffusion layer, etc. may be inserted appropriately, if necessary.

In addition, the transparent electrode 17 and the n-type electrode 11 may be provided respectively on the surface and rear surface. The n-type electrode 11 may be made in a grid form. The surface may be a p-type electrode instead of the transparent electrode, and the p-type electrode may be made in a grid form.

### <Method for Manufacturing Semiconductor Light Emitting Device>

Next, a method for manufacturing the semiconductor light emitting device 200 according to the fifth embodiment will be described with reference to FIGS. 15A to 15H.

The superlattice semiconductor layer 213 can be prepared by the use of a molecular beam epitaxy (MBE) method or a metalorganic chemical vapor deposition (MOCVD) method. The mixed crystal ratio of the quantum-dot layers 222a (222b) and the size of the quantum-dot layers 222a (222b) can be adjusted by changing composition ratios of raw materials, growth temperatures, pressures, deposition time, etc.

On the method for manufacturing the semiconductor light emitting device 200, the semiconductor light emitting device 200 including a superlattice structure can be manufactured by the use of, for example, a molecular beam epitaxy (MBE) method, a metalorganic chemical vapor deposition (MOCVD) method, or the like which is excellent in film thickness control. The method for manufacturing the semiconductor light emitting device 200 (selective growth) will be described now with reference to FIGS. 15A to 15H.

For example, an n-GaAs(111)B substrate (n-type semiconductor layer 1) is cleaned with an organic cleaning solution, then cleaned with a sulfuric acid cleaning solution, and further subjected to water cleaning, and subsequently, an SiO₂ film is stacked as the mask layer 2 as shown in FIG. 15A.

The mask layer 2 is a layer that forms no energetically stable materials with raw materials for the quantum-dot nanowires 230a (230b), and that includes a material in which the raw materials for the quantum-dot nanowires 230a (230b) are sufficiently large in diffusion length. Materials for the mask layer 2 include SiO₂ in the case of using InAs or GaAs as a material for the quantum-dot nanowire 230a (230b).

After stacking the mask layer 2, subsequently, as shown in FIG. 15B, openings 35a and 35b are formed respectively in plane regions PR1 and PR2 of the SiO₂ film surface with the use of, for example, electron lithography. In the fifth embodiment, the openings 35a and 35b have the different diameters as shown in FIG. 15B. In addition, techniques such as photolithography and nanoimprint technology may be used instead of electron lithography.

Subsequently, the n-type semiconductor layer 1 is placed in an MOCVD system. As shown in FIG. 15C, core layers 5a and 5b are formed respectively in the openings 35a and 35b formed on the n-type semiconductor layer 1. The core layers 5a (5b) preferably use the same material as the n-type semiconductor layer 1, but may use different materials therefrom. The core layers 5a (5b) also have a role as buffer layers, and serve as layers for improving the crystalline quality of light absorption layers to be formed thereon, and for example, GaAs layers are formed as the core layers 5a (5b).

Subsequently, the quantum-dot layers 222a (222b) and the barrier layers 220a (220b) are formed on the core layers 5a (5b), for which there are a growth mode of stacking a raw material in a gas phase directly on the quantum-dot nanowires 230a (230b) and a growth mode of stacking a raw material diffused from the mask layer 2 onto the quantum-dot nanowires 230a (230b). Even when raw materials supplied for the formation of the quantum-dot nanowires 230a (230b) temporarily put on the mask layer 2, the raw materials on the mask layer 2, because of being energetically unstable, evaporate again or run up onto the energetically more stable quantum-dot nanowires 230a (230b). Therefore, the raw materials are not stacked on the mask layer 2, but stacked on the quantum-dot nanowires 230a (230b), and it thus becomes possible to grow a semiconductor layer of the quantum-dot layers 222a (222b) and barrier layers 220a (220b) only on the quantum-dot nanowires 230a (230b), while the semiconductor layer of the quantum-dot layers 222a (222b) and barrier layers 220a (220b) is not formed on the mask layer 2.

Subsequently, quantum-dot layers 222a (222b) are formed as shown in FIG. 15D. For example, In_{0.3}Ga_{0.7}As is used as a material for the quantum-dot layers 222a (222b). It is possible to grow the quantum-dot layers 222a (222b) only on the quantum-dot nanowires 230a (230b) (z direction) almost without growing in the x and y directions under specific conditions (hereinafter, referred to as axial growth).

In the axial growth, for the formation of the quantum-dot nanowires 230a (230b), there are considered to be two modes: the growth mode of stacking a raw material in a gas phase directly on the quantum-dot nanowires 230a (230b); and the growth mode of stacking a raw material diffused from the mask layer 2 onto the quantum-dot nanowires 230a (230b), as mentioned previously. In the present invention, the mode of growing raw materials directly onto the quantum-dot nanowires 230a (230b) during the growth of the quantum-dot nanowires 230a (230b) is made dominant by providing the openings 35a (35b) to serve as a basis for the growth of the quantum-dot nanowires 230a (230b) at a high density in the mask layer 2, and the quantum-dot nanowires 230a (230b) with high uniformity even in highly-stacked cases are thus considered to be achieved. On the other hand, it is considered that it is also possible to make a growth mode dominant, in which raw materials are diffused from the mask layer to the uppermost surfaces of quantum-dot nanowires to form quantum-dot nanowires, by appropriately changing the density of the quantum-dot nanowires (the distance between the quantum-dot nanowires) and the growth conditions. Accordingly, when the density of quantum-dot nanowires is changed for each type of the plane regions to optimize the growth conditions, it is also possible to adopt the mode of growing raw materials directly onto quantum-dot nanowires in a relatively high-density region, the mode of growing raw materials diffused from a mask layer to the uppermost surfaces of quantum-dot nanowires in a low-density region, and a growth mode of both the modes mixed at a moderate density. When the density of quantum-dot nanowires is changed for growth for each plane region as described above, it is possible to form a quantum-dot nanowire structure in which quantum dots differ in composition and length in the stacking direction for each type of plane regions.

In addition, the control of the growth conditions (growth mode) can also change the quantum dots formed in quantum-dot nanowires in length in the stacking direction, and in composition, for each of quantum-dot nanowires with different diameters. More specifically, the quantum-dot layers 222a and 222b can vary from each other in length in the stacking direction.

The area density of openings 35a (35b) is preferably 4 openings/μm² or more, further preferably 16 openings/μm² or more, further preferably 25 openings/μm² or more, further preferably 36 openings/μm² or more, and further preferably 100 openings/μm² or more.

Furthermore, as for the structure of the quantum-dot nanowires 230a (230b), the ratio of the structure to the plane region PR1 (PR2) may be 5% or more, and further preferably 5% to 50% or more, when the plane region PR1 (PR2) is viewed from the stacking direction (above in the z direction).

With the thus increased density, the mode of stacking raw materials directly onto the quantum-dot nanowires 230a (230b) during the growth of the quantum-dot nanowires 230a (230b) is considered to be made dominant, and thus, in addition to the achievement of the quantum-dot nanowires 230a (230b) with high uniformity even in highly stacked cases, the emission intensity can be achieved advantageously when the nanowires are applied to a semiconductor light emitting device. In addition, the amounts of materials used can be reduced dramatically as compared with thin-film quantum-dot structures formed by SK growth or the like, thereby leading to a reduction in cost.

The periodic placement of quantum-dot nanowires 230a (230b) at a high density equalizes the growth conditions for each quantum-dot nanowire 230a (230b), and can thus achieve the quantum-dot nanowires 230a (230b) with high uniformity.

The use of the manufacturing method can determine the growth positions of the quantum-dot nanowires 230a (230b) in advance, thus making it easy to design the superlattice structure, and making it possible to form the structure of the quantum-dot nanowires 230a (230b) with a desired emission spectrum.

The structure of the quantum-dot nanowires 230a (230b) formed by the axial growth has strain relaxed in the x and y directions, so that strain energy will not be accumulated in the quantum-dot layers 222a (222b). Thus, the high-quality and highly uniform quantum-dot layers 222a (222b) can be formed in the quantum-dot nanowires 230a(230b), without causing any dislocations, and almost without variation in the size of the quantum-dot layer 222a (222b). Therefore, the high-quality quantum-dot nanowires 230a (230b) can be formed in a direction perpendicular to the n-type semiconductor layer 1 (z direction) as shown in FIG. 15E, by alternately supplying the material required for the formation of the quantum-dot layer 222a (222b) and the material required for the formation of the barrier layers 220a (220b).

The stacking number of the thus stacked quantum-dot layers 222a (222b) which have a substantially uniform size is preferably is 2 or more, further preferably 5 or more, further preferably 10 or more, further preferably 30 or more, further preferably 50 or more, further preferably 100 or more, further preferably 300 or more, and further preferably 600 or more per quantum-dot nanowire 230a (230b).

For example, when the number of the layers is 30, it is possible to achieve the area density of quantum dots on the order of 1.0×10¹¹/cm² to 5.0×10¹¹/cm², and for example, when the number of the layers is 600, it is possible to achieve the area density on the order of 1.0×10¹¹/cm² to 1.0×10¹³/cm².

It is to be noted that when the highly-stacked quantum-dot nanowires 230a (230b) were actually prepared by using the method according to the present invention, it was confirmed that at least 600 quantum-dot layers 222a (222b) were formed uniformly. The formation of these highly-stacked quantum dots can provide the semiconductor light emitting device 200 with a high emission intensity.

As shown in FIG. 15E, the shell layer 14 may be formed after forming the quantum-dot nanowires 230a (230b). The shell layer 14 may be doped with nothing, n-type doped, or p-type doped. It is to be noted that a material containing a p-type dopant such as Zn (for example, Diethylzinc: DEZ) is introduced simultaneously as a raw material in order to form the shell layer 14 as a p-type semiconductor layer.

Further, the shell layer 14 of p-type semiconductor may be provided by itself, or may be separately provided in addition to the shell layer 14 of n-type semiconductor. In addition, while an example of using n-type GaAs for the substrate and p-type GaAs for coating (shell layer 14) the quantum-dot nanowires 230a (230b) has been provided, the reversed structure may be employed, and a plurality of types of shell layers 14 may be used without limitation to only one type. For example, the outer side of the p-type GaAs layer may be further covered with an AlGaAs layer. In addition, the shell layer 14 may have the same material as the n-type semiconductor layer 1 or the p-type semiconductor layer 15, or have another material.

The shell layer 14 has a role for stabilization of the quantum-dot nanowire surfaces and/or as a carrier transport layer, and thus desirably has a bandgap that is at least equivalent as compared with the smallest bandgap among the n-type semiconductor layer 1, the p-type semiconductor layer 15, and the barrier layers.

Subsequently, as shown in FIG. 15F, the gap between the quantum-dot nanowires 230a (230b) in the superlattice semiconductor layer 213 is filled with a resin 10 such as, for example, BCB (benzocyclobutene). In addition, the same material as the barrier layers 220a (220b) may be used instead of the resin 10.

The resin 10 is subjected to partial etching with the use of, for example, RIE (Reactive Ion Etching) with CHF3/O2 plasma. The region opened by the partial etching is provided to make contact with an external circuit. The difference in selectivity allows the resin 10 to be preferentially etched.

Finally, the p-type semiconductor layer 15 is formed as shown in FIG. 15H. The transparent electrode 17, and further, the n-type electrode 11 are formed to form the semiconductor light emitting device 200 including a superlattice structure. For example, an AuGeNi/Au material can be used for the n-type electrode 11. The electrodes can be formed by, for example, electron-beam deposition. In addition, an ITO transparent electrode is used for the transparent electrode 17.

A contact layer may be provided on the p-type semiconductor layer 15.

While the method for manufacturing the semiconductor light emitting device 200 has been described above, the present invention is not to be limited to these manufacturing methods or configurations. For example, while the n-type semiconductor layer 1 is used in the manufacturing method according to the fifth embodiment, a p-type semiconductor may be used as a substrate. In such a case, an n-type semiconductor may be used in place of the p-type semiconductor layer 15. Furthermore, the quantum-dot nanowires 230a (230b) may be n-type doped. For example, Si and Zn may be used respectively as the n-type dopant and the p-type dopant. Other n-type dopants include, for example, S, Se, Sn, Te, and C.

While electron lithography is used for the SiO₂ patterning in the manufacturing method according to the fifth embodiment, the SiO₂ pattern can be also formed by other approaches. For example, nanoimprint and photolithography may be used for the patterning. The use of these approaches is suitable for mass production at low cost.

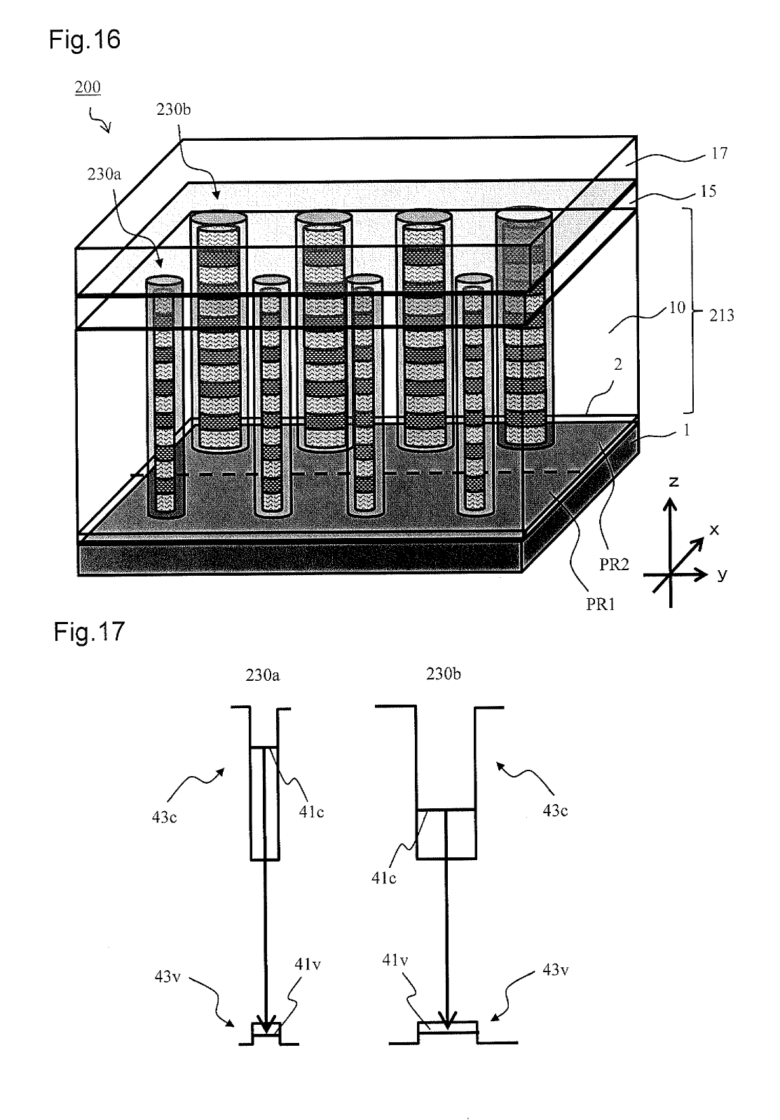

Next, the structure of the semiconductor light emitting device 200 including the superlattice semiconductor layer 213 according to the fifth embodiment of the present invention will be described with reference to FIGS. 16 and 17.

FIG. 16 is a diagram illustrating the structure of the semiconductor light emitting device according to the fifth embodiment of the present invention.

As shown in FIG. 16, the semiconductor light emitting device 200 is prepared by forming the superlattice semiconductor layer 213 in which quantum-dot nanowires 230a and 230 of different diameters are uniformly arranged respectively in different plane regions PR1 and PR2 on the same substrate, for example, at an area density of 4 nanowires/μm² or more. The quantum-dot nanowires 230a and 230b differ from each other only in diameter. More specifically, the quantum-dot layers 222a (222b) all have the same composition, and differ in size in the x-y plane.

In addition, it is preferable to shorten the distance between the quantum-dot layers 222a (222b) in the quantum-dot nanowire 230a (230b), because minibands 42c and 42v are formed between the quantum dots to make carriers likely to pass between the minibands.

[First Modification Example of Fifth Embodiment]

FIG. 17 is a diagram illustrating a structure according to a modification example of the semiconductor light emitting device shown in FIG. 16.

FIGS. 17A and 17B are respectively diagrams schematically illustrating band structures of the quantum-dot nanowires 230a and 230b.

As indicated by arrows in FIGS. 17A and 17B, luminescence is produced by radiative recombination from a quantum energy level 41c in a conduction band 43c to a quantum energy level 41v in a conduction band 43v, while the emission wavelengths vary depending on the diameters of the quantum-dot nanowires 230a and 230b and the thicknesses of the quantum dots in the z direction. Specifically, as the quantum-dot nanowire 230a (230b) is smaller in diameter, and as the quantum dot is smaller in thickness in the z direction, the energy is increased at the quantum energy level 41c in the conduction band 43c.

Next, methods for evaluating the quantum-dot nanowire 230a (230b) will be described.

Information on the quantum-dots in the quantum-dot nanowire 230a (230b), such as size, uniformity, dislocation, and how orderly the quantum-dot layers 222a (222b) are arranged in the z direction can be confirmed by TEM observation, or by SEM observation.

The n-type dopant concentration in the quantum-dot nanowire 230a (230b) can be confirmed by SIMS (Secondary Ion Mass Spectrometry).

It is to be noted that the examples provided therein are by way of example, and respective materials such as substrates, buffer layers, quantum dot layers 222a (222b), dopants, electrodes for use in the semiconductor light emitting device 200 including the superlattice structure according to the present embodiment, cleaning agents, substrate treatment temperatures, manufacturing equipment for use in each process, etc. are not limited to the examples given herein.

[Second Modification Example of Fifth Embodiment]

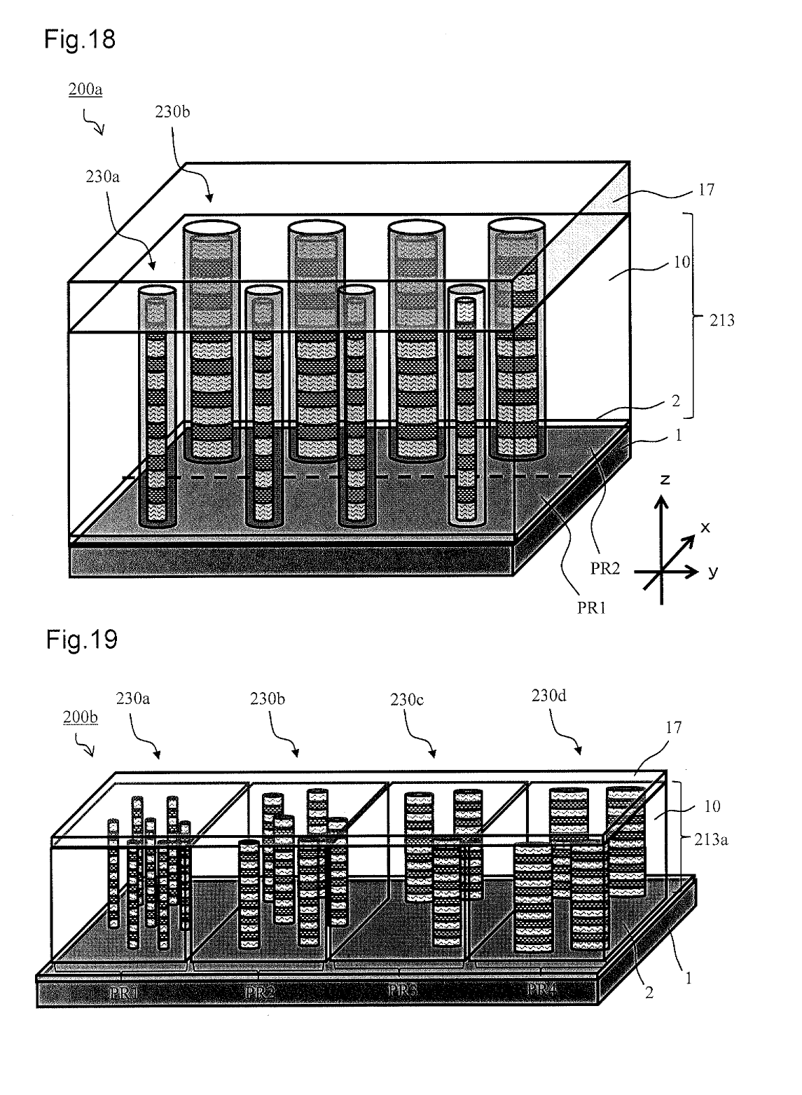

Next, a configuration of a second modification example 200a of the semiconductor light emitting device 200 shown in FIG. 16 will be described with reference to FIG. 18.

FIG. 18 is a diagram illustrating a configuration according to a modification example of the semiconductor light emitting device shown in FIG. 16.

As shown in FIG. 18, quantum-dot nanowires 230a and 230b that include quantum-dot layers 222a (222b) of equal length in the stacking direction (z direction) in each quantum-dot nanowires 230a (230b) and have two types of different diameters are arranged respectively in different plane regions PR1 and PR2 in the xy plane.

The difference from the configuration in FIG. 16 is that the semiconductor light emitting device 200a has a structure without the p-type semiconductor layer 15 on the top side of the semiconductor light emitting device 200 to make direct contact with a transparent electrode 17.

[Third Modification Example of Fifth Embodiment]

Next, a configuration of a third modification example 200b of the semiconductor light emitting device 200 shown in FIG. 16 will be described with reference to FIG. 19.

FIG. 19 is a diagram illustrating a configuration according to a third modification example of the semiconductor light emitting device shown in FIG. 16.

FIG. 19 show a structure of quantum-dot nanowires 230a to 230d of different diameters arranged for each of four types of plane regions PR1 to PR4 constituting the same substrate (n-type semiconductor layer 1) surface. The approach for manufacturing the semiconductor light emitting device 200b is the same as shown in FIGS. 15A to 15H. While the InGaAs material has been described in the present invention, the same configuration can be also obtained with an InGaN material, and LEDs of R/G/B can be configured, thereby allowing for use as, for example, a light source for communication.

It is to be noted that while the structures of the shell layer 14, etc. are omitted in FIG. 19 for the explanation, the same applies in the case of including the shell layer 14.

In addition, a detector can be configured with the use of the quantum-dot nanowire structure. For example, when an InGaN material is used, an R/G/B detector can be configured.

The quantum-dot nanowire structure has the advantage of being large in light-receiving area with respect to the area occupied by the substrate, and can thus constitute a small-size light emitting device, LED, or CCD camera.

<Relationship between Quantum-Dot Nanowire and Diagram Illustrating Band Structure>

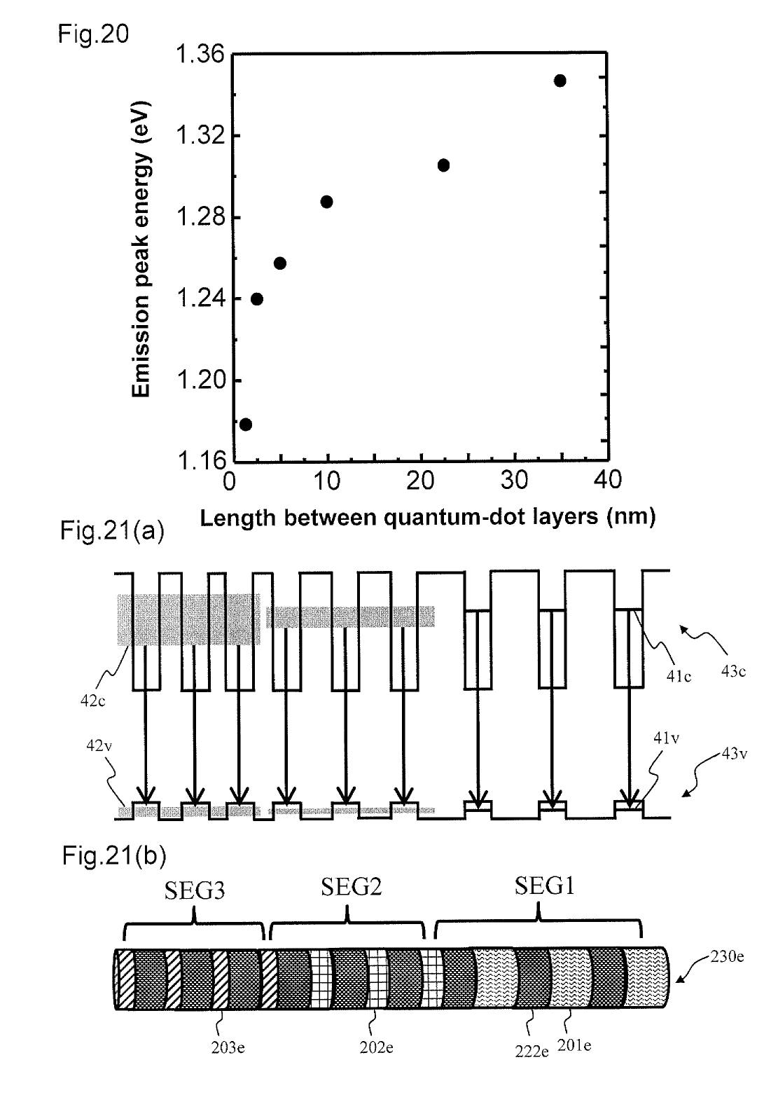

Next, the relationship between the quantum-dot nanowire shown in FIGS. 15A to 15H and the band structure thereof will be described with reference to FIGS. 3A to 3D and FIG. 20.

As shown in FIG. 3D, when the adjacent quantum energy levels 41c and 41v isolated respectively couple to form the minibands 42c and 42v (shaded areas in FIG. 3C), the emission energy is decreased (that is, the wavelength is increased), because the minibands 42c and 42v have energy widths so as to produce the luminescence from the miniband lower ends. In addition, the formation of the minibands 42a and 42v facilitates the transfer of carriers, and efficiently injects the carriers, thereby causing the semiconductor light emitting device 200a to efficiently emit light.

FIG. 20 is a graph showing the relationship between the length between quantum-dot layers in the quantum-dot nanowire in FIGS. 3A to 3D, and emission peak energy of the layer.

The horizontal axis in FIG. 20 indicates the length (nm) between the quantum-dot layers, whereas the vertical axis therein indicates emission peak energy (eV) of the quantum-dot layer.

FIG. 20 is the result of carrying out an experiment on the quantum-dot nanowire 230a which has a quantum-dot material of In_{0.7}Ga_{0.3}As, a quantum-dot length of 3 nm in the stacking direction (z direction), a quantum-dot diameter of about 40 nm, a nanowire material of GaAs, and a nanowire diameter of about 80 nm in the structure of FIGS. 3A to 3D, and is a diagram showing the relationship between the length between adjacent quantum-dot layers 222a, and the emission wavelength of the layer. In addition, the stacking number of quantum dots was 50.

As shown in FIG. 20, it is determined that the emission wavelength varies with changes in the interval (length) between the quantum-dot layers 222a, and in particular, it is determined that the emission wavelength increases sharply (the energy decreases sharply) with decrease in the interval between the quantum-dot layers 222a. The emission energy of the quantum-dot nanowire can be changed by taking advantage of this behavior.

Next, the structure of a quantum-dot nanowire 230e that has therein a plurality of regions with different distances between quantum-dot layers 222a will be described with reference to FIGS. 21A and 21B.

FIGS. 21A and 21B are diagrams illustrating the relationship between the barrier layer length in a quantum-dot nanowire and the band structure of the layer.

FIG. 21A is a diagram schematically illustrating a band structure of the quantum-dot nanowire 230e which has the structure of a plurality of regions with different distances between the quantum-dot layers 222a (FIG. 21B).

FIG. 21B shows the structure of the quantum-dot nanowire 230e with the nine quantum-dot layers 222e of the same size and composition buried therein. As shown in FIG. 21B, the quantum-dot nanowire 230e includes three segments of SEG1, SEG2, and SEG3 where the quantum-dot layers 222e are constant in length while barrier layers 201e, 202e, and 203e in the respective segments SEG1, SEG2, and SEG3 are different in length from each other.

In FIG. 21B, the length in the stacking direction is made shorter in the order of the barrier layers 201e, 202e, and 203e. The presence or absence of minibands formed and the energy widths of the minibands can be varied by varying the interval between the adjacent quantum-dot layers 222e, that is, the thicknesses of the barrier layers 201e, 202e, and 203e in this way. Taking advantage of this feature, the thicknesses of the barrier layers 201e, 202e, and 203e are varied, for example, for every three quantum-dot layers 222e to produce three types of emission wavelengths from the quantum-dot nanowire 230e. Accordingly, broadband light that is large in spectrum width can be freely created by providing any number of regions with different distances between the quantum-dot layers 222e. For example, a broadband Gaussian-type emission spectrum can be obtained.

As shown in FIG. 21A, in the segment SEG 1, the interval between the quantum-dot layers 222e is long, and there are independently quantum energy levels 41c and 41v respectively in a conduction band 43c and a valence band 43v. However, as the interval between the quantum-dot layers 222e in the quantum-dot nanowire 230e is shorter, as shown in the segments SEG2 and SEG3, the wave functions of the adjacent quantum-dot layers 222e overlap with each other for each of the conduction band 43c and the valence band 43v, and the quantum energy levels 41c and 41v couple to form minibands 42c and 42v (shaded areas in the segments SEG2 and SEG3 in FIG. 20A). The formation of the minibands 42a and 42v facilitates the transfer of carriers, and efficiently injects the carriers, thereby causing the semiconductor light emitting device 200a to efficiently emit light.

### Sixth Embodiment

Next, a semiconductor light emitting device 200c including a superlattice semiconductor layer 213c according to the sixth embodiment of the present invention will be described with reference to FIGS. 22A to 22H.

FIGS. 22A to 22H are diagrams illustrating a process for manufacturing a semiconductor light emitting device including a superlattice structure according to the sixth embodiment of the present invention.

It is to be noted that sections similar and corresponding to those in the process for manufacturing the semiconductor light emitting device 200 shown in FIGS. 15A to 15H are denoted by the same reference numerals, and descriptions of the sections will be skipped. The same applies to a seventh embodiment.

As shown in FIG. 22H, the semiconductor light emitting device 200c with quantum-dot nanowires have an arrangement of quantum-dot nanowires 301a (301b) that have different diameters between plane regions PR1 and PR2 in the x-y plane and include quantum-dot layers 222a and 2221a (222b and 2221b in the plane region PR2) of different lengths in the stacking direction (z direction). On the other hand, barrier layers 220a (220b) are the same in length.

As a specific manufacturing method, as shown in FIG. 22B, a mask layer 2 is formed, and openings 35a and 35b that are different in diameter (size) between the plane regions PR1 and PR2 are then formed in the mask layer 2. Next, as shown in FIG. 22C, after forming core layers 5a and 5b corresponding to the openings 35a and 35b, quantum-dot layers 222a (222b) and barrier layers 220a (220b) are alternately stacked in the plane region PR1 (PR2). Then, as shown in FIGS. 22E to 22H, quantum-dot layers 222a and 221a (222b and 221b) of different lengths are stacked in the stacking direction of the quantum-dot nanowire 301a (301b).

The use of this approach can change the quantum-dot layers in size intentionally in a controllable manner, thus forming high-quality quantum-dot layers without any dislocations. In addition, a diversity of bandgaps can be formed by arranging the quantum-dot nanowires 301a (301b) including the quantum-dot layers 222a and 221a (222b and 221b) which have a plurality of types of lengths in the stacking direction.

The use of this approach can change the quantum-dot layers in size in the height direction in a controllable manner while relaxing strain, thereby forming different types of high-quality quantum-dot layers with fewer dislocations or defects. In addition, this structure can produce a broadband Gaussian-type emission spectrum, and achieve the semiconductor light emitting device 200c with low power consumption.

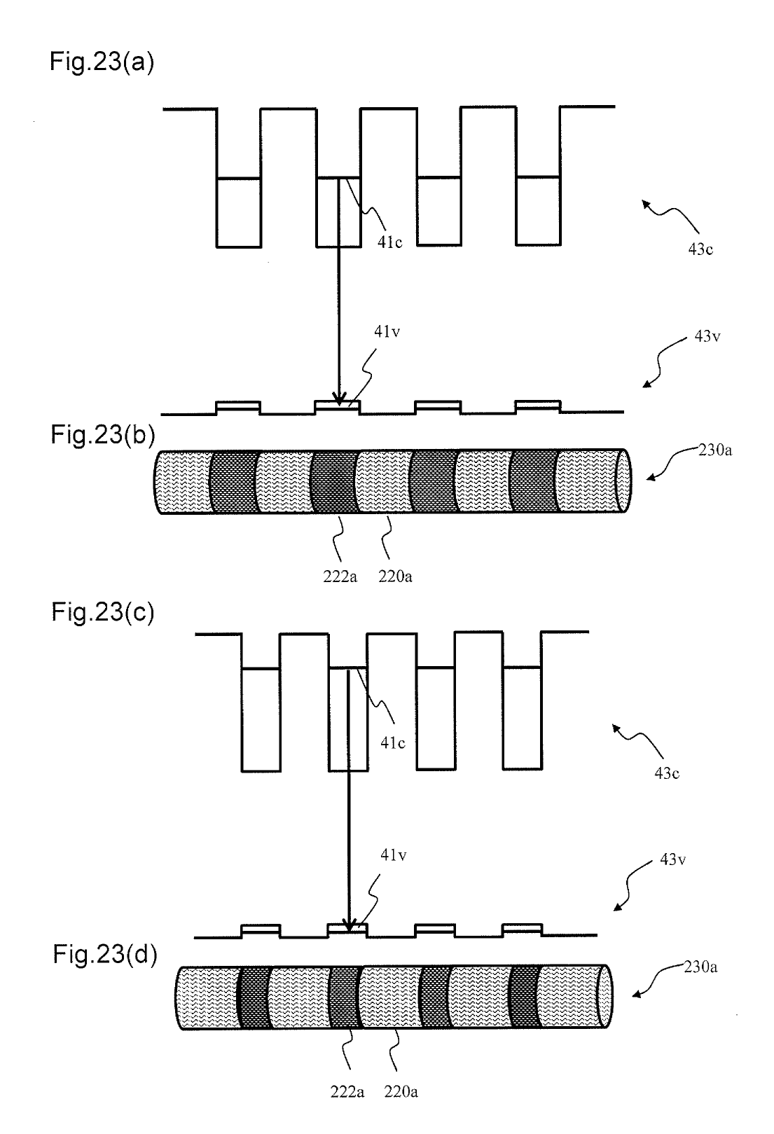

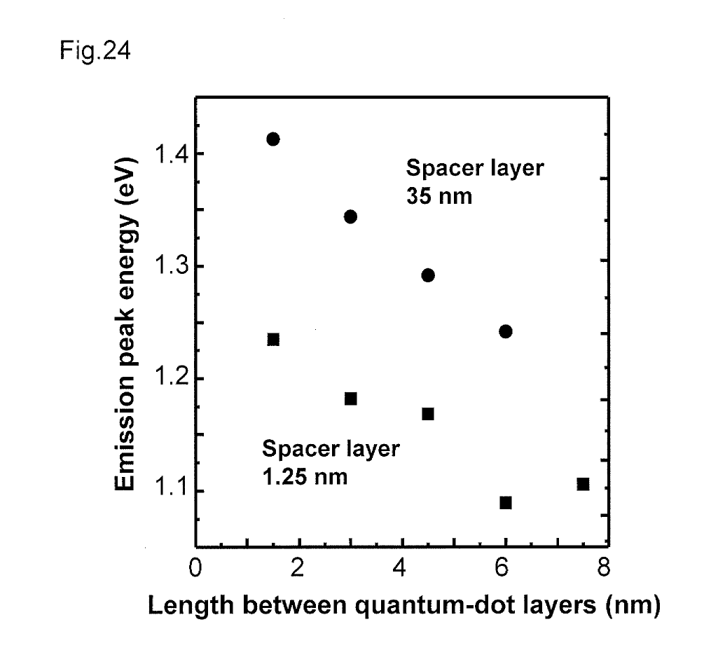

Next, the relationship between a quantum-dot nanowire and the band structure thereof will be described with reference to FIGS. 23A to 23D and FIG. 24.

FIGS. 23A to 23D are diagrams illustrating the relationship between the length of a quantum-dot layer in a quantum-dot nanowire and the band structure of the layer. In FIGS. 23B and 23D, the barrier layers 220a have the same material composition.

The difference between FIGS. 23B and 23D is the length of the quantum-dot layers 222a in the stacking direction, and FIG. 23B shows a structure including the quantum-dot layers 222a longer in the stacking direction than those in FIG. 23D.

FIG. 23A is a diagram schematically illustrating a band structure corresponding to FIG. 23B, whereas FIG. 23C is a diagram schematically illustrating a band structure corresponding to FIG. 23D.

A quantum energy level 41c is strongly affected by the quantum dot size, and the quantum energy level 41c is higher as the size is smaller. Accordingly, in the structure in FIG. 23D, the quantum energy level 41c is increased to increase the emission energy, as compared with the structure in FIG. 23B.

FIG. 24 is a graph showing the relationship between the length of the quantum-dot layer in the quantum-dot nanowire in FIGS. 23A to 23D, and emission peak energy of the layer.

The horizontal axis in FIG. 24 indicates the length (nm) of the quantum-dot layer in the stacking direction, whereas the vertical axis therein indicates emission peak energy (eV) of the quantum-dot layer.

FIG. 24 is a diagram showing the relationship between the thickness of the quantum-dot layer 222a and emission peak energy in the quantum-dot nanowire 230a where the quantum-dot layer 222a has a material of In_{0.7}Ga_{0.3}As, the quantum-dot layer 222a is about 40 nm in diameter, the quantum-dot nanowire 230a has a material of GaAs, and the quantum-dot nanowire 230a is about 80 nm in diameter, and is a result obtained from an experiment. The measurement was made on two types of 35 nm and 1.25 nm for the length of the barrier layer 220a in the stacking direction (spacer layer). From FIG. 24, it is determined that light of a different wavelength is radiated depending on the length of the quantum-dot layer 222a.

As shown in FIG. 24, it is determined that the emission peak energy is varied by changing the length of the quantum-dot layer 222a in the stacking direction. The emission energy of the quantum-dot nanowire 230a can be freely changed by taking advantage of this behavior, and desired emission energy can be thus obtained. In addition, the emission wavelength varied depending on the thickness of the spacer layer is believed to be due to the difference in how the wave functions of adjacent quantum dots overlap (the presence or absence of minibands formed).

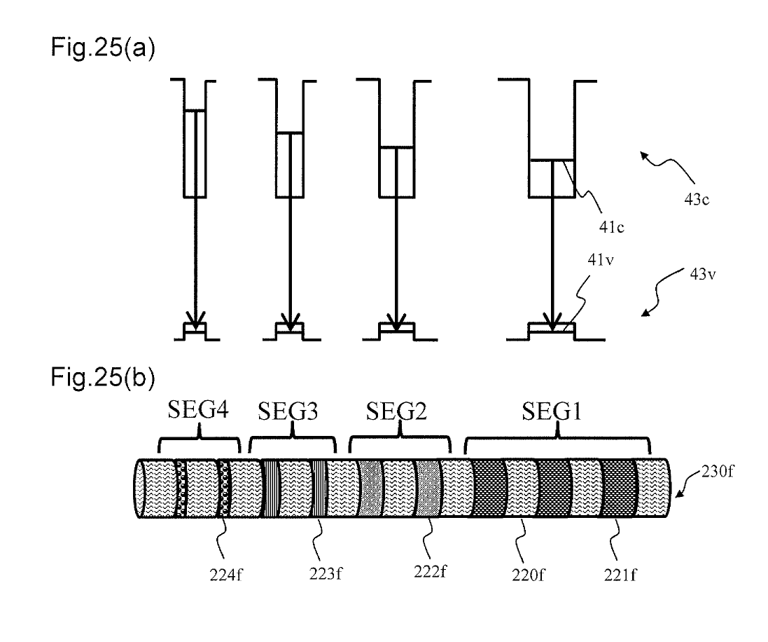

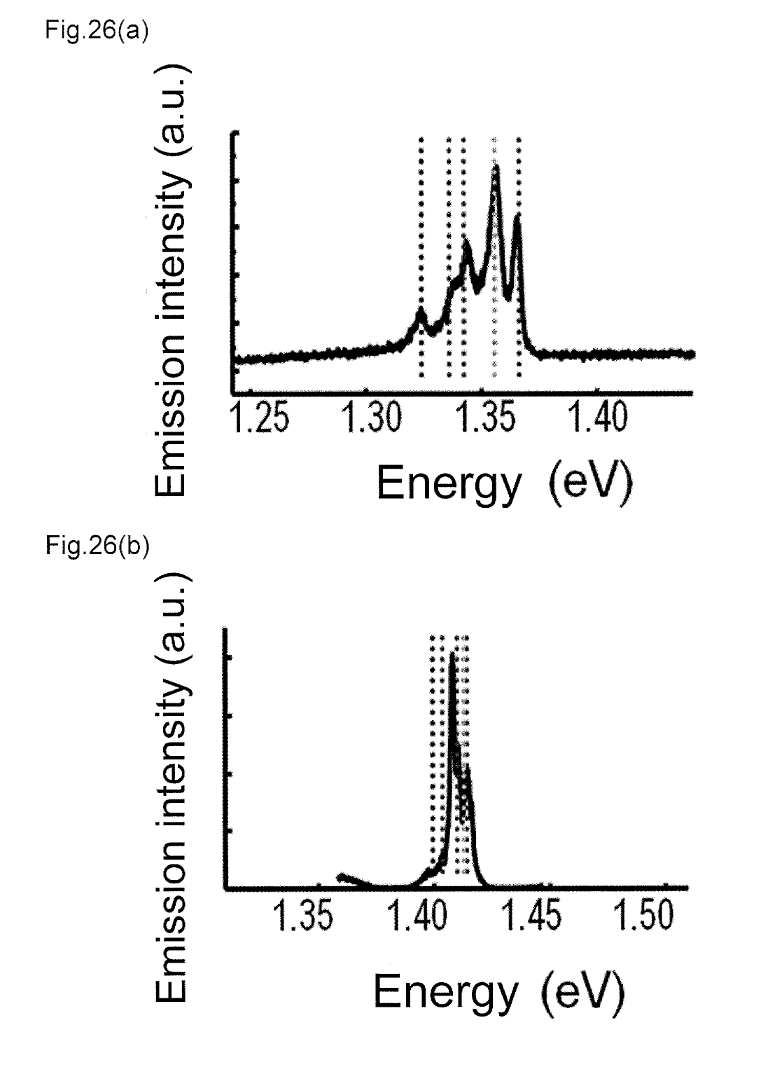

Next, the structure of one quantum-dot nanowire 230f that has therein a plurality of regions where quantum-dot layers have the same composition and different lengths in the stacking direction (z direction) will be described with reference to FIGS. 25A and 25B and FIGS. 26A and 26B.

FIGS. 25A and 25B are diagrams illustrating the relationship between the length of a quantum-dot layer in a quantum-dot nanowire and a diagram schematically illustrating the band structure of the layer.

FIG. 25A is a diagram schematically illustrating a band structure of the quantum-dot nanowire 230f, which has a structure of a plurality of regions with quantum-dot layers different in length in the stacking direction (z direction) (FIG. 25B).

The structure in FIG. 25B, which is similar to the structure in FIG. 21B, has quantum-dot layers which are the same in composition and different only in length. This configuration radiates light of a different wavelength depending on the length of the quantum-dot layer.

As shown in FIG. 25B, the quantum-dot nanowire 230f includes four segments of SEG1, SEG2, SEG3, and SEG4 where the barrier layers 220f are constant in length in the stacking direction (spacer layers) while quantum-dot layers 221f, 222f, 223f, and 224f in the respective segments SEG1, SEG2, SEG3, and SEG4 are different from each other in length in the stacking direction. In FIG. 25B, the length in the stacking direction is made shorter in the order of the quantum-dot layers 221f, 222f, 223f, and 224f.

On the other hand, as shown in FIG. 25A, in the segment SEG 1, the quantum-dot layer 221f has the longest length in the stacking direction, and there are independently quantum energy levels 41c and 41v respectively in a conduction band 43c and a valence band 43v. However, as the distance between the quantum-dot layers in the quantum-dot nanowire 230f is shorter, the quantum energy level 41c in the conduction band 43c is increased as shown in the segments SEG2, SEG3, and SEG4. Therefore, the energy from radiative recombination is made higher in the order of SEG1, SEG2, SEG3, and SEG4, and the emission wavelength is longer as the quantum-dot layer is longer.

It is to be noted that the structure in FIG. 21B may be combined with the structure in FIG. 25B.

FIG. 26A is a graph showing the relationship between the length of the quantum-dot layer in the quantum-dot nanowire in FIGS. 25A and 25B, and emission peak energy of the layer. FIGS. 26A and 26B are results obtained from experiments.

The horizontal axis in FIG. 26 indicates emission energy (eV), whereas the vertical axis therein indicates emission intensity (astronomical unit). Vertical dashed lines indicate the positions of emission peaks. FIGS. 26A and 26B are diagrams showing the relationship between emission energy and emission intensity, for a structure of five layers of quantum dots stacked while gradually changing the length of the quantum-dot layer in the stacking direction in FIG. 26A and for a structure of five layers of quantum dots stacked while keeping the length of the quantum-dot layer equal in the stacking direction in FIG. 26B, in the quantum-dot nanowire 230f where the quantum-dot layer has a material of In_{0.7}Ga_{0.3}As, the quantum-dot layer is about 40 nm in diameter, the distance between adjacent quantum-dot layers (spacer layer) is 280 nm, the quantum-dot nanowire 230f has a material of GaAs, and the quantum-dot nanowire 230f is about 80 nm in diameter. In FIG. 26A, five emission peaks are observed which correspond to the five quantum dots which differ in length in the stacking direction, and a broad spectrum is thus observed. On the other hand, almost no emission peak separation is observed in FIG. 26B. From these figures, it is determined that the emission spectrum and the emission energy can be controlled by adjusting the lengths of quantum-dot layers in the stacking direction in one nanowire, and a desired emission spectrum can be thus obtained.

### Seventh Embodiment

Next, a semiconductor light emitting device 200d including a superlattice semiconductor layer 213d according to the seventh embodiment of the present invention will be described with reference to FIGS. 27A to 27H.

FIGS. 27A to 27H are diagrams illustrating a process for manufacturing a semiconductor light emitting device including a superlattice structure according to the seventh embodiment of the present invention.

As a specific manufacturing method, FIGS. 27B to 27D are the same as the same as the sixth embodiment (FIGS. 22B to 22D). The difference from the sixth embodiment is that quantum-dot layers 222a and 2221a (222b and 2221b) are stacked which have the same length in the stacking direction of quantum-dot nanowires 302a (302b) and have, however, different materials and mixed crystal ratios as shown in FIGS. 27E to 27H.

The use of this approach can change the quantum-dot layers in material and mixed crystal ratio intentionally in a controllable manner, thus forming high-quality quantum-dot layers without any dislocations. In addition, a diversity of bandgaps can be formed by arranging the quantum-dot nanowires 302a (302b) including the quantum-dot layers 222a and 2221a (222b and 2221b) which have a plurality of types of lengths in the stacking direction.

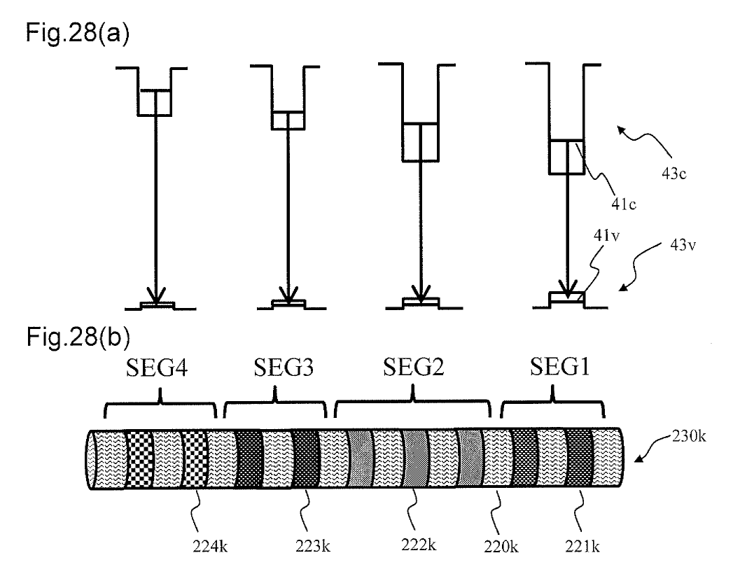

Finally, the structure of one quantum-dot nanowire 230k that has therein a plurality of regions where quantum-dot layers are the same in length but different in composition will be described with reference to FIGS. 28A and 28B.

FIGS. 28A and 28B are diagrams illustrating the relationship between the composition of a quantum-dot layer in a quantum-dot nanowire and a diagram schematically illustrating the band structure of the layer.

FIG. 28A is a diagram schematically illustrating a band structure of the quantum-dot nanowire 230k, which has a structure of a plurality of regions with quantum-dot layers different in composition (FIG. 28B).

As shown in FIG. 28B, the quantum-dot nanowire 230k includes four segments of SEG1, SEG2, SEG3, and SEG4 where the barrier layers 220k and quantum-dot layers are constant in length while the quantum-dot layers 221k, 222k, 223k, and 224k in the respective segments SEG1, SEG2, SEG3, and SEG4 are different from each other in composition.

On the other hand, as shown in FIG. 28A, a quantum energy level 41 in a conduction band 43c also varies as shown in the segments SEG1, SEG2, SEG3, and SEG4, reflecting compositional variations of the quantum-dot layers in the quantum-dot nanowire 230k. Therefore, the energy from radiative recombination also varies among SEG1, SEG2, SEG3, and SEG4.

FIG. 28B shows the structure of the one quantum-dot nanowire 230k in which the quantum-dot layers 221k, 222k, 223k, and 224k of the same length are different in composition. This configuration radiates light of a different wavelength for each composition of the quantum-dot layers. In FIG. 28B, for example, the first to second quantum-dot layers 221k from the right are the same in composition, the next three quantum-dot layers 222k are the same in composition, the next two quantum-dot layers 223k are the same in composition, and the next two quantum-dot layers 224k are the same in composition. For example, when the quantum dots are formed from InₓGa₁₋ₓAs, this type of structure can be achieved by varying the composition x of In.

FIG. 28A shows a diagram schematically illustrating band structures of a conduction band 43c and a valence band 43v, and indicates luminescence between quantum levels by arrows. Any types of quantum-dot layers may be adopted which have different compositions (four types in FIG. 28B), and the combination number quantum-dot layers which are the same in composition may be any number (sets of 2 layers, 3 layers, 2 layers, and 2 layers from the right in FIG. 28B). In FIG. 28A, the energy amount of the emission wavelength (the length of the arrow) is monotonically changed, but not limited to the monotonic change. In addition, while the quantum-dot layers (all of the nine quantum-dot layers in FIG. 28) are supposed to be all the same in length, the thickness may vary in combination with the structure in FIG. 25B.

As described above, desired emission spectra can be freely created by arbitrarily changing the types of quantum-dot layers which have different compositions, or the combination number of quantum-dot layers which have the same composition. In addition, the emission intensity can be increased by increasing the number of quantum dots per quantum-dot nanowire, or forming a higher density of quantum-dot nanowires in the plane. So far, stacking of 600 quantum dots per nanowire, the in-plane density has succeeded in the formation of quantum-dot nanowires at 16 nanowires/μm². In addition, a semiconductor light emitting device can be obtained which has a broadband and Gaussian spectrum suitable for the emission wavelength band for OCT, and a semiconductor light emitting device with low power consumption can be thus obtained.

While the present invention has been described above with reference to the embodiments, the present invention is not to be considered limited to these embodiments. Various modifications can be made to the present invention within the scope defined by the claims. Thus, the technical scope of the present invention also encompasses embodiments achieved by combining technical means appropriately modified within the scope defined by the claims.

What is claimed is:

1. A superlattice structure comprising:
a plurality of quantum-dot nanowires extending in a substantially vertical direction from a plane region;
wherein the quantum-dot nanowires have a structure of barrier layers and quantum-dot layers alternately stacked on the plane region, and the quantum-dot nanowires are substantially the same in diameter in a stacking direction and substantially uniformly arranged at an area density of 4 nanowires/μm² or more.

2. The superlattice structure according to claim 1, wherein the quantum-dot nanowires have at least two types of diameters.

3. The superlattice structure according to claim 1, wherein the quantum dot nanowires are formed on a base material surface including at least two types of plane regions, and the quantum-dot nanowires have different structures for each type of the plane regions.

4. The superlattice structure according to claim 1, wherein the quantum dot nanowires comprise the quantum-dot layers of at least two types of lengths in the stacking direction.

5. The superlattice structure according to claim 1, wherein the quantum dot nanowires comprise the quantum-dot layers of at least two types of compositions.

6. The superlattice structure according to claim 3, wherein the quantum dot nanowires comprise the barrier layers of at least two types of lengths in the stacking direction.

7. The superlattice structure according to claim 1, wherein an interval between the quantum-dot nanowires adjacent to each other is 30 nm to 500 nm.

8. The superlattice structure according to claim 1, wherein the quantum-dot nanowires have a diameter of 5 nm to 100 nm.

9. The superlattice structure according to claim 1, wherein the quantum-dot nanowires have 30 to 600 layers.

10. The superlattice structure according to claim 3, wherein the quantum-dot nanowires have different diameters for each type of the plane regions.

11. The superlattice structure according to claim 3, wherein the quantum-dot nanowires have different compositions for each type of the plane regions.

12. The superlattice structure according to claim 3, wherein the quantum-dot nanowires have different area densities for each type of the plane regions.

13. The superlattice structure according to claim 1, wherein the quantum-dot nanowires are arranged periodically with a constant repeating period, as viewed from a direction perpendicular to the plane region.

14. The superlattice structure according to claim 1, wherein a ratio of the structure to the plane region is 5% to 50% when the plane region is viewed from the stacking direction.

15. The superlattice structure according to claim 1, wherein the area density is 20 to 100 nanowires/pmt or more.

16. A semiconductor device comprising:
a p-type semiconductor layer, an n-type semiconductor layer, and a superlattice semiconductor layer sandwiched between the p-type semiconductor layer and n-type semiconductor layer;
wherein the superlattice semiconductor layer comprises the superlattice structure according to claim 1.

17. A semiconductor light emitting device comprising the semiconductor device according to claim 16, wherein the superlattice semiconductor layer emits light having at least two types of emission wavelengths.

18. The semiconductor light emitting device according to claim 17, the superlattice structure emits light having an emission wavelength for a Gaussian-type emission spectrum over the entire quantum-dot nanowires.

19. A method for manufacturing a superlattice structure comprising the steps of:
forming a mask layer on a plane region;
providing a plurality of openings with an area density of 4 openings/μm² or more in the mask layer;
and forming a plurality of quantum-dot nanowires by alternately stacking barrier layers and quantum-dot layers in a substantially vertical direction through the plurality of openings.

20. The method for manufacturing a superlattice structure according to claim 19, wherein the mask layer is formed on a base material surface including at least two types of plane regions
